(19) United States
(12) Patent Application Publication
(10) Pub. No.: US 2025/0020742 A1
(43) Pub. Date: Jan. 16, 2025

(54) APPARATUS FOR DETECTING ANALYTES

(71) Applicant: QUANTUM IP HOLDINGS PTY LIMITED, Melbourne (AU)

(72) Inventors: Paul Jeremy King, Melbourne (AU); Camden Yeung-Wah Lo, Melbourne (AU)

(73) Assignee: QUANTUM IP HOLDINGS PTY LIMITED, Melbourne (AU)

(21) Appl. No.: 18/715,240

(22) PCT Filed: Dec. 2, 2022
(86) PCT No.: PCT/IB2022/061736

§ 371 Date: May 31, 2024

(30) Foreign Application Priority Data
Dec. 2, 2021 (AU) 2021903912

(51) Int. Cl. G01R 33/12; B01L 3/00; G01R 33/00

(52) U.S. Cl. CPC G01R 33/1269; B01L 3/502761; G01R 33/0017; G01R 33/0094; B01L 2300/0663; B01L 2400/043

(57) ABSTRACT

Described is an apparatus comprising magnetisable particles adapted for binding to an analyte, the apparatus comprising a sensing zone comprising least an array of magnetic field sensors, a sample introduction device configured to introduce the sample to the sensing zone, optionally a field generator (optimised for magnetic and/or electric field generation) if the magnetisable particles do not have an aligned dipole moment, a controller connected to receive signals from the array of magnetic and/or electric field, the controller configured to determine an amount of analyte in the sample based on the signals received from the array of magnetic and/or electric field sensors, and an additional feature selected from one or more of a set and reset module or capability for performing a set/reset of the magnetic sensors, a data transmission layer, that is configured to shield the signals being transmitted from the one or more magnetic sensors, a plurality of magnetic field transmission zones corresponding to an area below each magnetic sensor, and a printed circuit board comprising one or more vias connecting to the magnetic field sensors.

### FIELD OF THE INVENTION

The invention relates to a device for detecting target analyte(s) in a sample, and more specifically, based on the use of nanoparticles and a sensor system for detecting the nanoparticles. The invention also relates to a method for detecting an analyte(s) in a sample, and more specifically, the use of nanoparticles and a sensor system.

### BACKGROUND OF THE INVENTION

There are many known devices and methods for detecting and quantifying target analytes in a sample based on the use of particles such as magnetic particles. Such devices and systems require an indirect method to quantify the analyte by detecting and measuring a complex that is bound to the analyte. Typically, such methods rely on a binding or recognition system whereby a visualisation aid is coated or linked to a binding molecule that binds to the analyte in the sample.

The detection and quantification of target analytes in a sample often need to be rapid, sensitive, qualitative and/or miniaturisable to fulfil the needs of in vitro diagnostics. Miniaturisation of devices can lead to slow and inefficient mixing of fluids due to an increase in viscous forces.

Point-of-care testing can reduce the turn-around time for diagnostic testing giving improved workflows and thus potentially aiding improved patient care. Such systems must include sensing technology to detect biomarkers (e.g. protein markers or nucleic acid markers). Magnetisable particles have been used for detecting analytes across manual assays for basic research to high throughput testing.

Some portable devices use electrochemical means for detection of analytes. For example, some such devices use potentiostat-type instruments to detect electrochemical signals generated by enzyme-based labels. Often, the labels generating the detectable electrochemical signals are further complexed with magnetic agents (for electromagnetically manipulating the complex) and binding agents (to bind target analytes). Such devices may be slower to obtain measurements.

Many existing devices for detecting analytes attached to magnetisable particles require complex configurations that are unsuitable or are not easily adapted for miniaturisation in point-of-care testing applications.

The use of magnetisable particles means that additional forces can be applied to the particles, for example, to separate bound from unbound particles.

An evaluation of the analytical performance of a detection methodology is based on the limit of quantification (LoQ) i.e. the lowest biomarker concentration that can be quantified with a given required precision.

GMR has been used in sandwich-type immunoassays (such as an ELISA), where the molecular target is immobilised on the sensor surface with the addition of tagged magnetic probes (see Koh and Josephson “Magnetic nanoparticle sensors” Sensors 2009: 9; 8130-45 and Yao and Xu “Detection of magnetic nanomaterials in molecular imaging and diagnosis applications” Nanotechnol. Rev 2014:3; 247-268).

Some techniques use superconducting quantum interference device (SQUID) to detect and measure Néel relaxation (misalignment of magnetic dipole) in magnetically labelled bacteria. In such techniques, a magnetic field is pulsed to cause magnetic dipole alignment and the subsequent dipole misalignment is detected.

It is an object of the present invention to address one or more of the abovementioned issues, and/or to provide a device for detecting an analyte, a method for detecting an analyte in a sample and/or to at least provide the public with a useful choice.

### SUMMARY OF THE INVENTION

In a first aspect we describe an apparatus comprising magnetisable particles adapted for binding to an analyte, the apparatus comprising:
a sensing zone comprising at least an array of magnetic field sensors,
a sample introduction device configured to introduce the sample to the sensing zone,
optionally a field generator (optimised for magnetic and/or electric field generation) if the magnetisable particles do not have an aligned dipole moment,
a controller connected to receive signals from the array of magnetic and/or electric field, the controller configured to determine an amount of analyte in the sample based on the signals received from the array of magnetic and/or electric field sensors, and
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv).

In a further aspect we describe an apparatus for sensing of a sample comprising magnetisable particles bound and unbound to an analyte, the apparatus comprising:
a sensing zone comprising at least an array of magnetic field sensors,
a sample introduction device configured to introduce the sample to the sensing zone when the bound and unbound magnetisable particles are in a fluidised state so that Brownian motion of bound and un-bound particles is induced when the sample is in the sensing zone,
a magnetic field generator provided the magnetisable particles do not have an aligned dipole moment,
a controller connected to receive signals from the array of magnetic and/or electric field sensors which represent relative differences in magnetic and/or electric fields of the bound and unbound magnetised particles, the controller configured to determine a relative amount of the analyte in the sample based on the signals received from the array of magnetic field sensors, and
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv).

In a further aspect we describe an apparatus for sensing of a sample comprising particles bound and unbound to an analyte, the apparatus comprising:
a sensing zone comprising at least an array of electric field sensors,
an electric field generator that generates a current having a standard sine wave pattern,
a sample introduction device configured to introduce the sample to the sensing zone when the bound and unbound particles are in a fluidised state so that Brownian motion of bound and unbound particles is induced when the sample is in the sensing zone,
a controller connected to receive signals from the array of electric field sensors which represent relative differences electric fields of the bound and unbound magnetised particles induced by their Brownian motion, the controller configured to determine a relative amount of the analyte in the sample based on the signals received from the array of magnetic or electric field sensors.

In a further aspect we describe a method for measuring an analyte in a sample comprising
providing an apparatus that comprises
a sensing zone comprising at least an array of magnetic field sensors,
a sample introduction device comprising magnetisable particles being coated with binding molecules complementary to a target analyte,
a field generator, provided the magnetisable particles do not have an aligned dipole moment, the field generator optimised for magnetic field generation if a magnetic field sensor is present,
a controller connected to receive signals from the array of magnetic field sensors which represent relative differences in magnetic fields of the bound and unbound magnetised particles, and
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv);
introducing a sample containing an analyte to be measured into the sample introduction device to bring the analyte into contact with the magnetisable particles to provide both analyte-bound magnetisable particles and unbound magnetisable particles,
the sample introduction device biasing the analyte-bound magnetisable particles and unbound magnetisable particles to the sensing zone to position the analyte-bound magnetisable particles and unbound magnetisable particles at the sensing zone,
changing the bias sufficient to release at least a portion of the analyte-bound magnetisable particles and unbound magnetisable particles from their position in the sensing zone, and
determining, via the controller, a relative amount of the analyte in the sample based on the signals received from the array of magnetic field sensors based on the Brownian motion of analyte-bound magnetisable particles and unbound magnetisable particles.

In a further aspect we describe a method for measuring an analyte in a sample comprising
providing an apparatus that comprises
a sensing zone comprising at least an array of electric field sensors,
an electric field generator that generates a current having a standard sine wave pattern,
a sample introduction device comprising particles being coated with binding molecules complementary to a target analyte,
a controller connected to receive signals from the array of electric field sensors which represent relative differences in electric fields of the bound and unbound particles induced by their Brownian motion, and
introducing a sample containing an analyte to be measured into the sample introduction device to bring the analyte into contact with the particles to provide both analyte-bound particles and unbound particles,
the sample introduction device biasing the analyte-bound particles and unbound particles to the sensing zone to position the analyte-bound particles and unbound particles at the sensing zone,
changing the bias sufficient to release at least a portion of the analyte-bound particles and unbound particles from their proximity to the sensing zone, and
determining, via the controller, a relative amount of the analyte in the sample based on the signals received from the array of electric field sensors based on the Brownian motion of analyte-bound particles and unbound particles.

Any one or more of the following embodiments may relate to any of the above aspects.

In one configuration the apparatus comprises
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv);

In one configuration the electric field generator has a frequency of 10, 100, 200, 300, 400, 500, 600, 700, 800, 900 or 1000 kHz, and suitable ranges may be selected from between any of these values.

In one configuration the electric field generator has a frequency of 0.1, 1, 2, 3, 4, 5, 6, 7, 8, 9 or 10 volts, and suitable ranges may be selected from between any of these values.

In one configuration the magnetisable particles may be magnetised before binding to the analyte, or before or during introduction of the sample to the magnetic sensing zone.

In one configuration the array of magnetic sensors comprises a set and reset coil/strap for performing set/reset of the magnetic sensors.

In one configuration the magnetic sensors are set/reset between readings.

In one configuration the plurality of magnetic sensors are connected in series to a calibration port such that one calibration signal is used to set/reset of the plurality of magnetic sensors.

In one configuration the magnetic sensors have a sampling rate of about 100 kHz to about 200 kHz.

In one configuration the sensing zone is provided on an upper surface of a circuit board.

In one configuration at least one magnetic field or electric generator is provided on a lower surface of the circuit board at a location corresponding to the sensing zone on the upper surface of the circuit board.

In one configuration the circuit board comprises a plurality of layers.

In one configuration the circuit board comprises at least one upper layer, a ground plane layer, and a lower layer.

In one configuration the circuit board comprises a data transmission layer, that is configured to shield the signals being transmitted from the one or more magnetic sensor from electromagnetic interference generated by the other components of the circuit board.

In one configuration the data transmission layer is positioned between the upper and lower layer.

In one configuration the circuit board comprises a plurality of magnetic field transmission windows, each transmission window defining a portion of the circuit board that is devoid of copper layers, and transmission window corresponding to an area of the circuit board below each magnetic sensor.

In one configuration the apparatus comprises a detection surface area of about 1 cm² to about 25 cm².

In one configuration the detection surface comprises about 6 to about 24 magnetic sensors.

In one configuration the array of magnetic sensors are closely packed.

In one configuration the apparatus further comprises enclosure for housing at least one circuit board.

In one configuration the enclosure further comprises an integrated display configured to render a diagnostic output obtained from the circuit board.

In one configuration the enclosure further comprises an integrated display and at least one circuit board is configured to perform the operation of a lab-on-a-chip device.

In one configuration the integrated display and a plurality of circuit boards are arranged in parallel is configured to perform the operation of a lab-on-a-bench device.

In one configuration the enclosure performing the operations of the lab-on-a-chip and lab-on-a-bench device is configured to be controlled by a user interface.

In one configuration the controller is configured to controllably bias one or more of the sample introduction device, field generators, array of sensors, amplifiers and filters.

In one configuration the controller is configured to control the bias of the sample introduction device.

In one configuration the sample introduction device biases the particles towards the sensors.

In one configuration the circuit board is about 10 cm² to about 100 cm² in size.

In one configuration the detection surface covers about 10% to about 50% of the circuit board surface

In one configuration the apparatus further comprises a sensor for detecting an orientation of the apparatus such that the apparatus is operable in any orientation.

In one configuration the sensor for detecting an orientation of the apparatus comprises one or more of a gyro-scope sensor, an inertial measurement unit, and an accelerometer.

In one configuration the one or more magnetic sensors are analog sensors.

In one configuration the one or more magnetic sensors comprise one or more of magneto-resistive, hall effect, and fluxgate sensors.

In one configuration the apparatus further comprises a signal processing module, wherein the signal processing module comprises one or more of:
an analog to digital converter,
an amplifier for amplifying the signal from the one or more magnetic sensors, and
a power supply.

In one configuration the sample introduction device is removable.

In one configuration the sample introduction device is integrated with the apparatus.

In one configuration the sensing zone comprises a plurality of wells.

In one configuration the plurality of channels are arranged in a cross-hatched configuration (multiplex design).

In one configuration the plurality of channels are arranged in a noncross-hatched configuration (parallel simplex design).

In one configuration the plurality of wells are preloaded with binding complexes.

In one configuration the binding complexes are provided in a gel.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7).

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting

In this specification, where reference has been made to external sources of information, including patent specifications and other documents, this is generally for the purpose of providing a context for discussing the features of the present invention. Unless stated otherwise, reference to such sources of information is not to be construed, in any jurisdiction, as an admission that such sources of information are prior art or form part of the common general knowledge in the art.

The term “comprising” as used in the specification and claims means “consisting at least in part of.” When interpreting each statement in this specification that includes the term “comprising,” features other than that or those prefaced by the term may also be present. Related terms “comprise” and “comprises” are to be interpreted in the same manner.

### BRIEF DESCRIPTION OF THE FIGURES

The invention will now be described by way of example only and with reference to the drawings in which:

FIG. 1 is a schematic representation of the components of the apparatus for detecting analytes.

FIG. 2 is a diagrammatic representation of the apparatus for detecting analytes.

FIG. 3 is an example embodiment of a microfluidic chip.

FIG. 4 is a functional block diagram of the apparatus for sensing of a sample comprising particles bound and unbound to an analyte according to an embodiment of the disclosure

FIG. 5 is the schematic/circuit diagram of the apparatus illustrating the input and output connections and different sensors modules.

FIG. 6 illustrates the schematic/circuit diagram of an embodiment of the sensing zone of the apparatus

FIG. 7 depicts the schematic/circuit diagram of an embodiment of the sensing zone of the apparatus

FIG. 8 is the schematic/circuit diagram of the signal processing module 800.

FIG. 9 depicts the schematic of the CM module according to an embodiment

FIG. 10 is the schematic of the power management module of the apparatus

FIG. 11 is the schematic of the display module of the apparatus

FIG. 12 is the schematic of the orientation detection module of the apparatus

FIG. 13 illustrates the schematic of the set/reset circuit of the apparatus

FIG. 14 is a 3-D illustration of a variant of the apparatus

FIG. 15 illustrates an embodiment of the touch screen the input user interface of the apparatus

FIG. 16 illustrates another embodiment of the touch screen the input user interface of the apparatus

FIG. 17 is the block diagram depicting the data generation and processing steps

### DETAILED DESCRIPTION

Described is an apparatus for sensing of a sample comprising particles bound and unbound to an analyte, the apparatus comprising a sensing zone comprising an array of magnetic or electric field sensors. The apparatus includes a sample introduction device that is configured to introduce the sample to the sensing zone when the bound and unbound particles are in a fluidised state. Without wishing to be bound by theory, Brownian motion of bound and unbound particles is induced when the sample is in the sensing zone. When a magnetic and/or electric sensor is present, the particles comprise magnetisable particles and the magnetisable particles are in a magnetised state when at the sensing zone. A field generator may be present, provided the magnetisable particles do not have an aligned dipole moment. That is, if the particles do not have an aligned dipole moment then a field generator is present, otherwise it is optional to include a field generator. The field generator is optimised for magnetic field generation if a magnetic field sensor is present and/or electrical field generator if an electric field sensor is present, the electrical field generator generating a current having a standard sine wave pattern. The apparatus also includes a controller connected to receive signals from the array of magnetic or both magnetic and electric field sensors which represent relative differences in magnetic or electric fields of the bound and unbound magnetised particles. The controller is configured to determine a relative amount of the analyte in the sample based on the signals received from the array of magnetic or electric field sensors. When a magnetic field sensor is used, the apparatus further comprises:
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv).

The particles may be positioned in the sensing zone by a biasing mechanism, such as the presence of a magnetic field. The apparatus described is based on the concept of measuring a detectable change in magnetic and/or electric field over time caused by changes in the magnetisable particles, such as translational and/or rotational movement of particles and analyte complexes relative to the sensing zone due to Brownian motion, and/or the degree of aggregation of the particle and analyte complexes.

The particles may be functionalised with binders (such as antibodies) that bind to analytes of interest. The particles used with the device may generate or be induced to generate a signal that is detectable and/or measurable by the sensing module (e.g. a magnetic or electric field sensor). For example, the particles may generate or be induced to generate a magnetic field, an electric field, luminescence, fluorescence (with excitation via lasers, LEDs, microLEDs or silicon photonics, for example), light absorbance, optical frustrated total internal reflection (induced using light sources such as lasers, LEDs, microLEDs or silicon photon, for example), ionic potential, vibration, acoustics, radiation that are detectable and measurable using the appropriate sensors.

The particle and analyte complexes may aggregate based on binder-bead interactions of adjacent complexes. The antibodies may be designed to bind a single antigen. When an analyte has used a position on an antibody, the antibody is no longer available for that adjacent complex interaction.

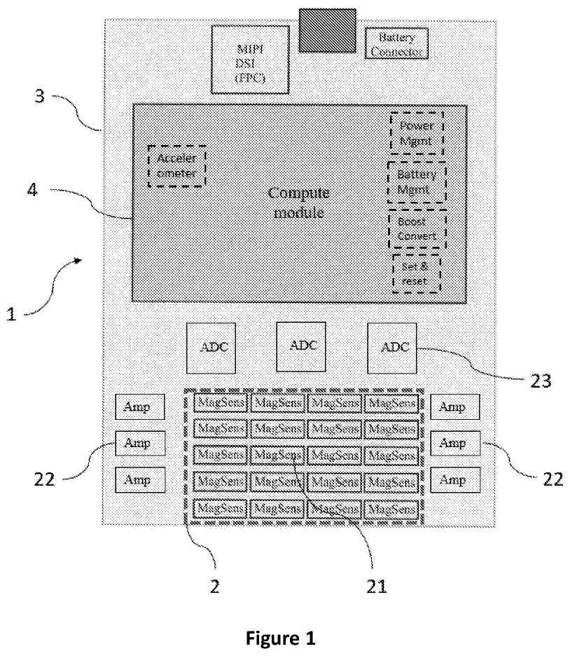

Shown in FIG. 1 is a schematic representation of an embodiment of the apparatus 1 for detecting analytes. In this embodiment, the apparatus comprises a detection surface 2, a circuit board 3, and a compute module 4. The detection surface 2 comprises the sensing zone which may include a plurality of magnetic sensors and/or electrical sensors or optical sensors 21.

Once the apparatus is turned on the signal output of the magnetic sensors 21 may be processed through a signal processing module 7 of the circuit board 3. The signal processing module may comprise a plurality of amplifiers 22, and analog-to-digital converters (ADC) 23. The compute module 4 comprises the controller (not shown). The apparatus 1 may also comprise one or more magnetic field generators (not shown).

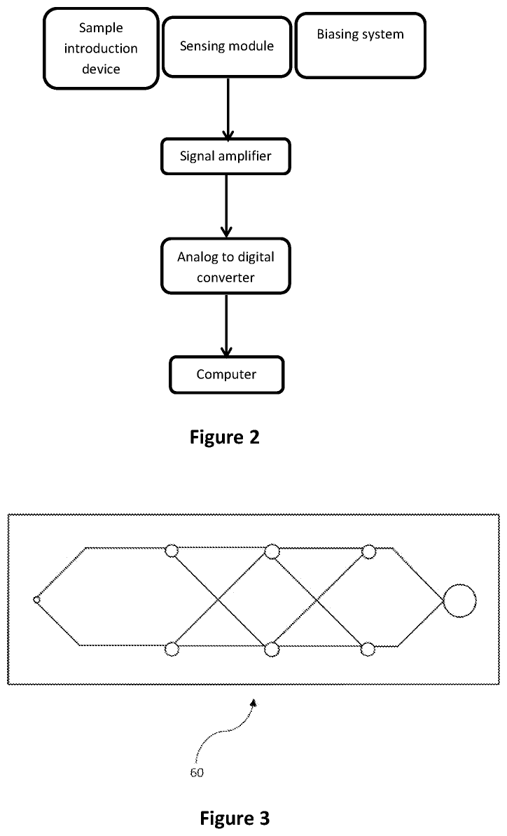

FIG. 2 is a diagrammatic representation of the apparatus for detecting analytes. In particular, the apparatus may broadly comprise a sensing module, a biasing system, a sample introduction device, and a signal processing module comprising a signal amplifier and an analog to digital converter.

The apparatus is capable of an accurate, rapid, and sensitive measurement of one or more analytes in a sample. For example, an embodiment of the apparatus (comprising 24 magnetic sensors, 24 amplifiers, three eight-channel analog-to-digital converters) may be capable of generating more than 450,000 high resolution data-points per channel per second, equating to more than 10 million data points per 25 second read series.

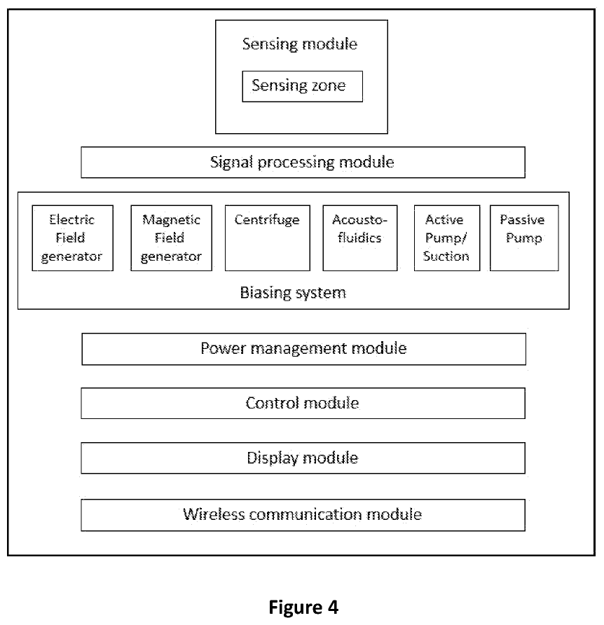

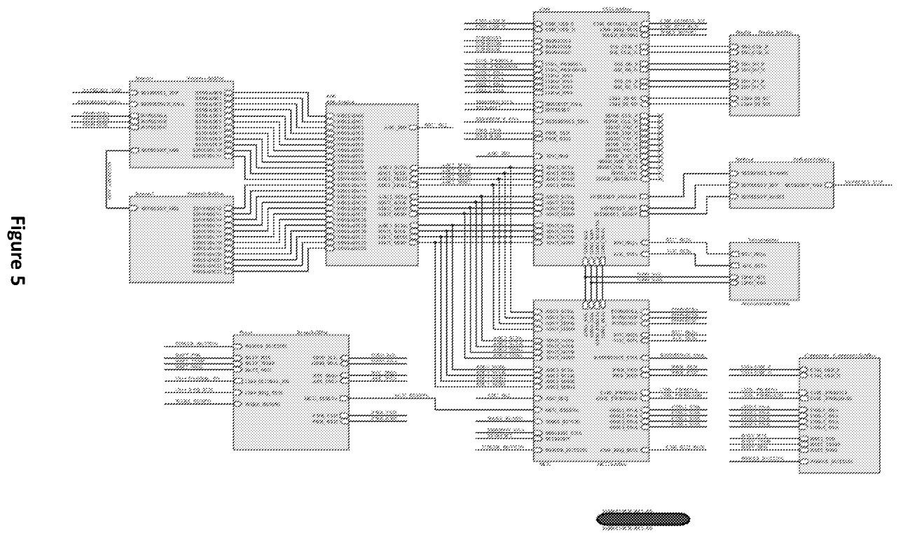

FIG. 4 is a functional block diagram of the apparatus for sensing of a sample comprising magnetisable particles bound and unbound to an analyte according to an embodiment. In this embodiment, the apparatus 400 may comprise a sensing module 401 configured to detect magnetic particles and output a signal from on-board magnetic or electric field sensors, a signal processing module 402 configured to receive and process the output of the received signals, a sample introduction device 403 configured to introduce the sample to the sensing zone, a power management module 405 configured to store energy and power different components of the apparatus, a control module 406, configured to perform on-board analysis on the sample by detecting a relative amount of an analyte in the sample, a display module 407 configured to render the results of the on-board diagnostics, and a wireless communication module 408 configured to wirelessly transmit analytical, telemetric, environmental and diagnostic data obtained from the sample.

In an implementation, the above modules of the apparatus may be provided in the form of interconnected circuit boards or a multi-layered PCB.

The apparatus 400 may further comprise a magnetic field generator 410, an electric field generator 411, an electro-magnetic field generator and an orientation measurement module 404 configured to measure the orientation of the device.

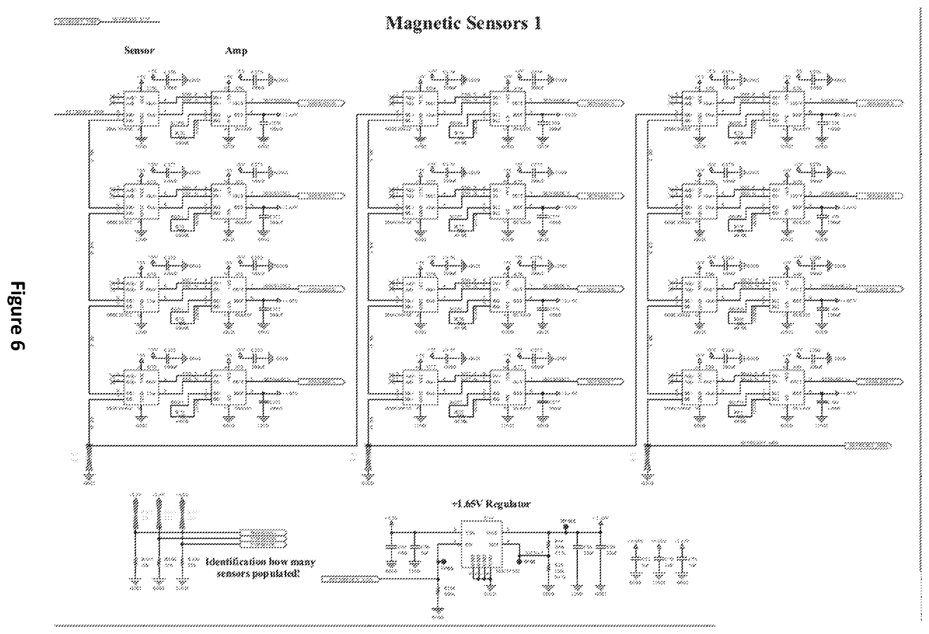

FIG. 5 shows a schematic/circuit diagram of the apparatus illustrating the input and output connections and different sensors modules used in the sensing process. As is evident from FIG. 5, the overall design of several modules is spread over multiple layers of the PCB. For example, the discrete schematic level articulations of the magnetic sensors, 1:1 sensors to amplifiers/set-reset function of the sensors, analog to digital converters, power management modules, display module and other various sub-system capabilities are depicted in the schematic form.

The compute module shown in FIG. 5 reflects the discrete design of the optional, compute capability for fully autonomous implementations of the apparatus. In some implementations, for example, in non-fully autonomous implementations of the apparatus, a micro controller unit (MCU) and USB-C/Wifi/BlueTooth connections securely stream data to a wirelessly/wire tethered secondary device such as a mobile phone or another compute device. This can occur between multiple device PCB ‘cores’ within a single case (veterinary and human clinical/laboratory applications).

The device may be configured to exclude component(s) where functions capabilities/outcomes can be achieved by a connected device such as, but not limited to, a cellular phone. Such capabilities may include, screen, user interface, software, network connection, data processing, encryption, power magnetometer, analog-to-digital convertor, accelerometer, gyroscope, battery, optical sensor, and speakers.

The apparatus 400 may comprise a compact form factor suitable for use as a portable point-of-care device. In addition to the compact form factor, the device achieves desired accuracy, sensitivity, and speed for detecting and quantitating analytes in samples in order to perform its function as a portable POC device.

In some embodiments, various components of the device may be provided one or more circuit boards. For example, the detection surface comprising magnetic sensors, the magnetic field generator(s), controller, analog-to-digital converter(s) (ADC), signal amplifier(s), and power supply may be provided on one or more circuit boards.

The components may be provided on separate but interconnected circuit boards as depicted in FIG. 5. For example, the detection surface or the sensing zone (including magnetic sensors), the magnetic field generator, the signal generation module, the signal processing module (including analog-to-digital converter (s (ADC), signal amplifier(s), orientation detection module, and power management modules may be provided on a primary circuit board, while the controller may be provided on a secondary circuit board connected to the primary board via connector suitable for maintaining data transmission and integrity.

The circuit board may be a printed circuit board (PCB). For example, the circuit board may be single sided, double sided, multi-layered, rigid, flexible, or rigid-flex.

The circuit board may comprise a plurality of circuitry layers (copper layers). For example, the circuit board may comprise 2, 3, 4, 5, 6, 7, 8, 9 or 10 circuitry layers.

The circuit board may comprise one or more ground plane layers. Multiple ground plane layers may be used to improve signal return and to reduce noise and interference to further improve the accuracy of the magnetic field sensor. The ground plane may be configured to control oscillation frequencies to remove or reduce interference.

The circuit board may comprise one or more data layers. Providing dedicated data layer(s) may optimise the integrity of data transfer between the various components of the device. For example, it may maintain the integrity of the signals from the magnetic sensors to the amplifiers, analog-to-digital converters, controller, and vice versa. Providing dedicated data layer(s) may optimise the integrity of data transfer between the various components of the apparatus. For example, it may maintain the integrity of the signals from the magnetic sensors to the amplifier(s), analog-to-digital converter(s), controller, and vice versa.

The detection surface of the apparatus may be provided on an upper surface of the circuit board. The detection surface defines the area which receives the microfluidic chip and in which one or more magnetic and/or electric sensors are provided for detecting changes in the magnetic field. The detection surface may be provided at or near an edge of the circuit board.

One or more magnetic field generators may be provided on a lower surface of the circuit board. The magnetic field generators may be provided at a location corresponding to a location of the detection surface on the upper surface of the circuit board.

The detection surface of the apparatus may be provided on an underside surface of the circuit board. The detection surface defines the area which receives the microfluidic chip and in which one or more magnetic and/or electric sensors are provided for detecting changes in the magnetic field. The detection surface may be provided at or near an edge of the circuit board.

One or more magnetic field generators may be provided on an upper surface of the circuit board. The magnetic field generators may be provided at a location corresponding to a location of the detection surface on the upper surface of the circuit board.

One or more magnetic field generators may be positioned above, below, adjacent, or in parallel with the circuit board.

The circuit board may comprise one or more magnetic field transmission windows configured to allow transmission of and/or focus the magnetic field generated by the magnetic field generators provided on the lower surface of the circuit board. The magnetic field transmission windows may comprise portions of the circuit board devoid of copper layers in specific areas. Each magnetic field transmission window may correspond to an area of the circuit board below each magnetic sensor.

The circuit board may comprise a dimension of about 5, 10, 15, 20, 25, 30, 35, 40, 45, 50, 55, 60, 65, 70, 75, 80, 85, 90, 95, or 100 cm², and suitable ranges may be selected from between any of these values.

The circuit board may have a footprint dimension similar to a credit card. For example, the circuit board may comprise a dimension of about 5.5×8.5×2.5 cm. The compact dimension of the circuit board enables the apparatus to have a relatively compact overall dimension to improve the portability, and therefore, usability of the apparatus as a point-of-care diagnostic device.

The circuit board may comprise a detection surface that is about 5, 10, 15, 20, 25, 30, 35, 40, 45, 50% of the circuit board surface.

Focus will now be will now be placed on describing in detail each module of the apparatus illustrated in FIGS. 4 and 5.

The sensing module (or detection unit) may comprise one or more sensors for detecting and measuring a change in a measurable signal over time due to the translational and rotational Brownian movement of the particles when released from their proximity to the sensor.

The sensors may detect and/or measure a change in detectable signals such as magnetism, current and/or voltage (including resistance and impedance), luminescence, fluorescence, light absorbance, optical frustrated total internal reflection, vibration, acoustics, ionic protentional, or radioactivity. In some embodiments, the sensors perform resistive pulse or electrical zone sensing.

The sensors may comprise magnetic field sensors, oscilloscopes, multimeter, current sensors, voltage sensors, photo sensors, optical sensors such as CMOS light sensors used in mobile phone cameras, MEMS sensors, scintillation counters and radiation sensors. In some embodiments, the sensors comprise sensing elements, for example, electrodes (anodes and cathodes), conductive coils, and conductive circuits.

The sensing module may comprise a sensing zone or a detection surface in which sensing of the change in magnetic field of magnetisable particles over time may occur. The detection surface may comprise one or more sensors capable of rapid and sensitive detection in the changes of magnetic field such as direction, strength, and flux.

The one or more sensors may comprise one or more magnetic field sensors.

The magnetic sensor may be selected from spintronic sensors, atomic magnetometers (AMs), nuclear magnetic resonance (NMR) systems, fluxgate sensors, Faraday induction coil sensors, diamond magnetometers, and domain walls-based sensors, vibration magnetic sensors, GMR/TMR/Wheatstone bridge sensors, etc.

The volumetric-based sensors, such as planar hall effect (PHE) sensors provide simple and rapid sample preparation and detection. Surface-based sensors, such as giant magnetoresistance (GMR) offer a lower detection limit (single particle) due to the short distance between the magnetisable particles and the sensor. The spintronic sensors may be selected from giant magnetoresistance (GMR), tunnel magnetoresistance (TMR), anisotropic magnetoresistance (AMR), and planar Hall effect (PHE) sensors.

The GMR effect was discovered in the 1980s and has traditionally been used in data recording. The spin valve provides higher sensitivity with a micron-sized design. A spin-valve GMR sensor consists of an artificial magnetic structure with alternating ferromagnetic and nonmagnetic layers. The magneto resistance effect is caused by the spin-orbital coupling between conduction electrons crossing the different layers. The variation in magnetoresistance provides quantitative analysis by this spin-dependent sensor. GMR sensors may be used to detect DNA-DNA or protein (antibody)-DNA interactions. The dimensions of the sensor array may be adjusted for the detection of individual magnetisable particles. GMR sensors may be used in combination with antiferromagnetic, ferromagnetic, ferrimagnetic, paramagnetic, superparamagnetic particles.

The planar Hall effect is an exchange-biased permalloy planar sensor based on the anisotropic magnetoresistance effect of ferromagnetic materials. The PHE sensor may be a spin-valve PHE or PHE bridge sensor. The PHE sensor may be able to carry out single-particle sensing.

Where a plurality of magnetic sensors are used, the plurality of magnetic sensors may be configured to comprise set/reset functionality. The set/reset for each magnetic sensor may be connected as a series circuit or connection for signalling and Input-Output.

The set/reset functionality may be integrated on the magnetic sensor, such as provided by the Bosch BMM 150 geomagnetic sensor which is a sensor that allows measurements of the magnetic field in three perpendicular axes. The use of such a sensor may simplify the design of the board, such as to negate the need for a data transmission layer. The use of such a sensor may provide for a detection surface area of 4 to 100 mm². The amplifier may be integrated into the sensor.

Where a plurality of magnetic sensors are used, the plurality of magnetic sensors may be configured as a series circuit or connection for the Set/Reset functionality, which eliminates hysteresis and sensor drift. That is, each magnetic sensor's Set/Reset functionality, of the plurality of magnetic sensors, are connected in series.

The accuracy and sensitivity of magnetic sensors may be negatively affected by external forces. In particular, magnetic fields and temperature change may disrupt the orientation of the magnetic domains in magnetic sensors. When disrupted, the orientation of the magnetic domain may be randomised which reduces the accuracy and sensitivity of the sensors.

To maintain a high level of accuracy and sensitivity, the magnetic sensors may be recalibrated periodically. For example, the magnetic sensors may be recalibrated after about 100, 80, 60, 40, 20, 10, 9, 8, 7, 6, 5, 4, 3, 2, or 1 reading(s) by the magnetic sensor.

The magnetic sensors may be recalibrated once per cycle of sample readings, where each cycle can consist of 10, 100, 1000, 10000, 100000 of readings by the magnetic sensor.

The magnetic sensors are recalibrated after each reading.

Recalibration of the magnetic sensors may be performed using a set and reset operation. Set and reset of the magnetic sensor realigns the orientation of the magnetic domains before each sampling by the sensor. Performing set and reset allows the sensor to recover from any disruption to the orientation of the magnetic domain such that the magnetic domains are in the optimal orientation for accurate and sensitive performance. Performing ‘set’ realigns all the magnetic domains of the magnetic sensor in a first direction, while a ‘reset’ realigns the magnetic domains of the magnetic sensors in a second direction opposite the first. Performing set and reset removes all randomness in the magnetic domain of the magnetic sensor.

The calibration set and reset can identify current, system-specific electromagnetic bias or interference of low to high frequency. This one-directional bias can then be allowed for within the system calculations to negate the effect of any such bias leading to improved accuracy of the sensor.

The one or more magnetic sensors may comprise a set/reset coil (strap) wound around the sensing elements (such as the magnetoresistive element) of the magnetic sensor. Calibration signals may be pulsed and transmitted through the set/reset coils to perform set and/or reset the magnetic sensors.

In an embodiment, the magnetic sensors may comprise an offset strap. The offset strap may allow for several modes of operation when a direct current is driven through it. These modes are: 1) Subtraction (bucking) of an unwanted external magnetic field, 2) nulling of the bridge offset voltage, 3) Closed loop field cancellation, and 4) Auto-calibration of bridge gain. The set/reset strap can be pulsed with high currents for the following benefits: 1) Enable the sensor to perform high sensitivity measurements, 2) Flip the polarity of the bridge output voltage, and 3) Periodically used to improve linearity, lower cross-axis effects, and temperature effects.

The magnetic sensors circuit may be connected to a calibration port. Calibration signals may be supplied via the calibration port to calibrate the magnetic sensors. The calibration signals may comprise a set calibration signal (pulse) and a reset calibration signal (pulse).

The series configuration of the magnetic sensor's set/Reset function allows a single or single set of calibration signal(s) to recalibrate the plurality of magnetic sensors. Such a configuration may improve the speed and reliability of the sensor calibration process. For example, calibration of magnetic sensors connected in a series configuration could be performed in hundred thousandths to millionths of second.

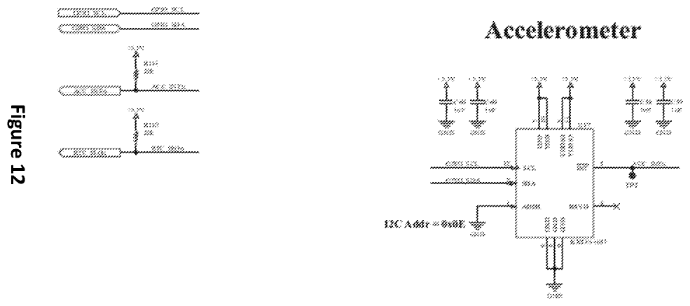

Referring to FIG. 13, this displays the set/reset circuit 1300 of the apparatus. The magnetic sensors 601 are set/reset by sending pulses of electric current. For example, the SR+ and SR-ports of the magnetic sensors are configured to receive the pulses of current to reset the sensors. The same amount of current may be applied to all the sensors connected in series at the same time.

The set/reset circuit may comprise a voltage booster circuit 1301. The voltage booster circuit 1301 may be configured to boost the voltage to set/reset all sensors simultaneously. The set/reset port 1301 may comprise a set/reset port configured to feed the current in the sensors in series.

In order to achieve a high level of accuracy and sensitivity, the magnetic sensors of the apparatus may comprise a high sampling rate. The magnetic sensors may sample at a sampling rate of about 10, 20, 30, 40, 50, 60, 70, 80, 90, 100, 110, 120, 130, 150, 160, 170, 180, 190, 200, 210, 220, 230, 240, or 250 kHz, and suitable ranges may be selected from between any of these values, (for example, about 10 to about 250, about 10 to about 200, about 10 to about 150, about 10 to about 100, about 100 to about 250, about 100 to about 200, about 100 to about 150 kHz.)

The ADC sampling rate of the magnetic sensors may have a sampling rate of about 100 kHz to about 200 kHz.

The plurality of magnetic sensors may have a sampling rate of about 150 kHz per channel.

The magnetic field sensor may be an on-chip magnetometer. The magnetic field sensor may have a sensitivity of at least 1 mV/V/gauss. In some embodiments, the magnetic field sensor may detect and/or measure a magnetic field of at least about 10 mGauss, 1 mGauss, 100 μGauss, or 10 μGauss.

The magnetic field sensor may comprise multiple axis, for example one, two or three-axis.

The magnetic field sensor may be a Honeywell HMC 1021S magnetometer. In another embodiment, the magnetic field sensor may be a Honeywell HMC1041Z magnetic sensor. In other embodiments, the magnetic field sensor may be selected from the group comprising Honeywell HMC 1001, HMC 1002, HMC 1022, HMC 1051, HMC 1052, HMC 1053, or HMC 2003 magnetometers.

The magnetic field sensor may comprise a bespoke magnetic field sensor having custom components.

In order to achieve a compact form factor with a high level of detection accuracy, sensitivity, and speed the detection surface of the apparatus comprises a high density of magnetic sensors per cm². Increasing the density of magnetic sensors allows more compact microfluidic systems to be used with the apparatus. Using more compact microfluidic systems advantageously improves the speed of the diagnostic due to the shorter distances for the sample to travel in the channel of the microfluidics system. More compact microfluidics also minimises the amount of dead volume (non-detection areas) on the microfluidic system which reduces the amount of sample required for diagnostics.

The detection surface may comprise a sensor density of about 3, 4, 5, 6, 7, 8, 9, 10, 11, 12, 13, 14, 15 magnetic sensors per cm².

To achieve a high level of sensor density, each magnetic sensor may be configured to have a minimal foot print to maximise the number of sensors providable within on the detection surface. In one embodiment, vias for the sensor are placed within the perimeter of the solder pads to enable the magnetic sensors to be positioned closer to each other to achieve a high sensor density configuration.

The connectors of the sensors may be configured through multiple independent planes of a multilayer printed circuit board such that the density of planar circuit connections can be increased without conflict or interference with other connections

Multiple magnetic sensors may be provided on the detection surface to simultaneously measure the change in magnetic field. For example, the detection surface may comprise two, three, four, five, six, seven, eight, nine, 10, 12, 14, 16, 18, 20, 22, 24, 26, 28, 30, 32, 34, 36, 38, 40, 42, 44, 46, 48, 50 magnetic sensors.

The magnetic field sensors may be provided in a relatively small area in the apparatus. For example, 24 magnetic field sensors may be provided to an area of about 13 mm×19 mm. Such a configuration enables faster sample-to-data times, due the shorter microfluidic channels that are used with this magnetic field sensor configuration. This configuration further enables a smaller and more portable apparatus.

The detection surface may comprise a surface area of about 1, 2, 3, 4, 5, 6, 7, 8, 9, 10, 12, 14, 16, 18 or 20 cm², and suitable ranges may be selected from between any of these values.

The apparatus may be configured as a mobile lab by tethering multiple apparatuses. Tethering multiple apparatuses expands the diagnostic capabilities of the apparatus. For example, two or more apparatuses may be tethered to obtain higher sensor numbers to further improve speed of analyte detection and quantitation across multiple samples. The apparatuses may be connected wirelessly or via a hardwired connection.

A case may be provided for tethering a plurality of apparatuses. The case may provide additional functionality to the apparatus. For example, the case may provide additional computing power, power supply, and communications systems.

The apparatus may comprise a modular architecture. For example, sensing modules having one or more detection surfaces maybe connectable to the apparatus to obtain a higher number of simultaneous reads further reducing sample to data time on a per analyte basis.

Multiple magnetic field sensors may be used simultaneously to measure the change in magnetic field. For example, 50, 60, 70, 80, 90, 100, 110 or 120 magnetic field sensors for small portable applications and in situ laboratory or clinical applications, and useful ranges may be selected between any of these values, (for example about 50 to about 120, about 50 to about 100, about 50 to about 90, about 50 to about 80, about 60 to about 120, about 60 to about 110, about 60 to about 90, about 70 to about 110, about 70 to about 90, about 80 to about 100 magnetic field sensors).

The sensing zone may comprise a plurality of electric field sensors. For example, 4, 8, 10, 14, 18, 22, 26, 30 or more electric field sensors

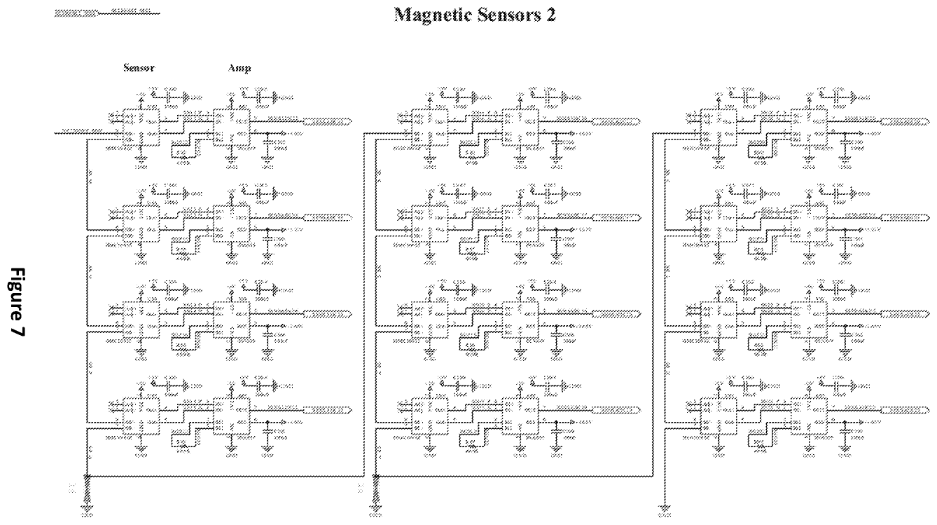

FIGS. 6 and 7 depict the schematic/circuit diagram of an embodiment of the sensing zone of the apparatus. The signal from each of the magnetic sensors 601 is fed into instrumentation amplifiers 602 for amplification. The sensing zone may comprise a voltage regulator 603 to regulate the reference voltage of the signal input to the instrumentation amplifier. The regulated reference signal input to the instrumentation amplifier may provide a consistent refined reference point to determine voltage changes against sample to sample voltage received from the sensor.

The sensing zone may further comprise a sensor population identifier module. The population identifier module is configured to identify how many sensors are populated on the PCB and in which positions which possible sensor locations have been populated with a sensor. This allows for various device variant and configurations from single PCB design.

Referring to FIG. 17, an instance of the data collection and processing step of the sensing module is depicted in the form of a block diagram. As illustrated, an instrumentation amplifier 1701 is configured to receive and amplify a reference signal 1702 and signals (e.g., voltage readings) from the magnetic sensor 1703. The amplified output signal from the instrumentation amplifier 1701 then undergoes the step of analog filtering 1704 where the raw data is filtered to eliminate noise. The processed analogue data is then fed onto an analog-to-digital converter 1705 where it is converted in to digital domain. The resultant signal from the ADC is then processed by the digital signal processing module 1706.

The sensing module 600 may comprise one or more instrumentation amplifiers configured to amplify the signal output from the magnetic sensors. The amplifiers may provide a large amount of gain from low level signals (up to 10,000 gain). The amplifiers may be a lower power amplifier with overvoltage protection. An example of a suitable instrumentation amplifier is the Texas Instruments INA819.

In one implementation, the sensing module 402 may comprise one or more analog-to-digital converters (ADCs). The conversion or sampling resolution may be 16, 24, 32, 64, 128, 256, or 512 bit.

In one implementation, the ADCs may be 16 or 24 bit and comprise 2, 4, 8, 16 channels. An example of a suitable ADC is the MCP3464 eight channel 16-bit Sigma-Delta ADC by Microchip Technology.

The signal output from the plurality of magnetic or electric field sensors of the sensing zone is stored and processed by the signal processing module 402. The signal output of the magnetic or electric field sensors may be a voltage reading that is proportional to the sensed magnetic field or emf. In an embodiment, the voltage reading from the magnetic field sensor may be amplified in magnitude to a higher voltage (in proportion to the original voltage reading) that is compatible with data processing and collection electronic components.

The apparatus may comprise an amplifier to magnetic sensor ratio of 1:1. This arrangement may optimise sensitivity and accuracy for each sensor. For example, an apparatus comprising 24 magnetic sensors comprises 24 amplifiers. A 1:1 ratio of amplifier to magnetic sensors enables a configuration where a single, isolated circuit is used for the entire analogue mode of data. This configuration may eliminate the possibility of sensor crosstalk/interference when running multiple sensors simultaneously, especially when the signals are low level.

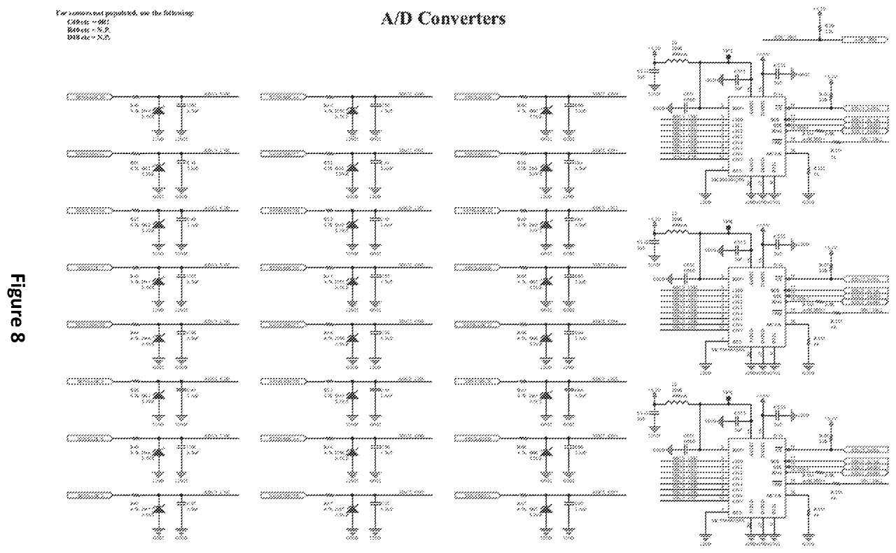

Referring to FIG. 8, the schematic/circuit diagram of the signal processing module 800 is illustrated. The signal processing module may be configured to process the amplified data output of the magnetic sensors. The amplified signal may be in the raw format and may comprise some remnant line noise or other activity/noise from the circuit board. This raw signal affected by noise is then filtered in the signal processing module through digital filtering techniques. As illustrated, the amplified signal from each of the sensors is fed into a filter module.

The apparatus may switch to DC power when reading the sensors to avoid noise from the circuit board.

The digital filter may be a low-pass filter. However, other filtering techniques may also be applied depending on the level of noise or filtering needed.

The signal processing module may further comprise a microcontroller or a microprocessor. The microprocessor may be a compute module (CM). The CM reflects the discrete design of the optional compute capability for fully autonomous implementations of the apparatus.

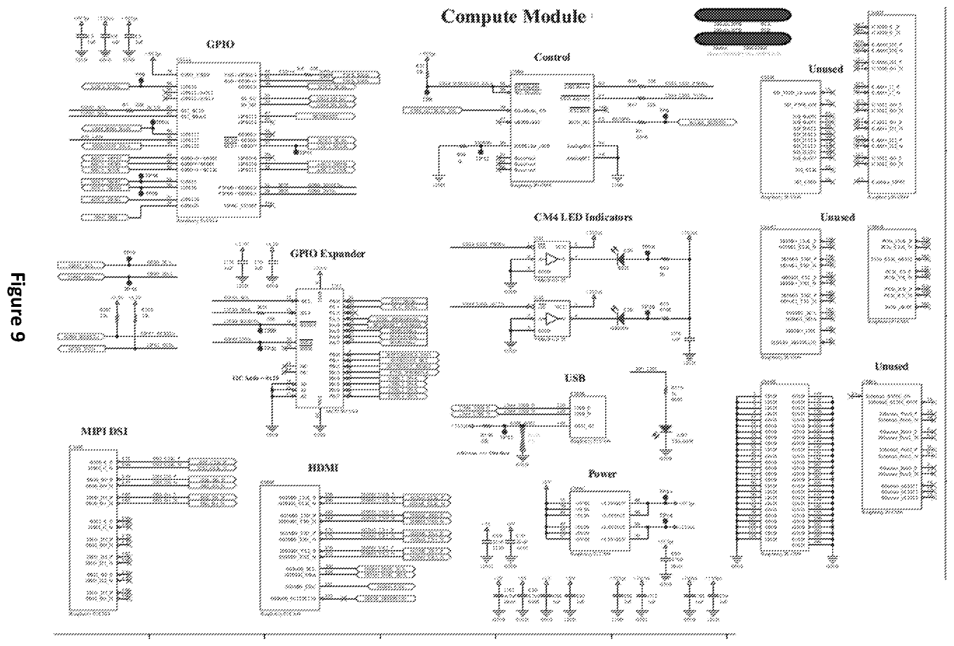

FIG. 9 depicts the schematic of the CM4 module 900. As illustrated, the CM4 module comprises GPIO interfaces 901 for many subsystem schematic elements including each of the three ADC modules 803. In an embodiment. The CM4 module may further comprise additional and/or separate GPIO pins in the form of a GPIO expander, to access and control other subsystems such as magnetic field generators, Set/Re-Set functions, and subsystem statuses.

The CM module may share video I/O ports with the PCB resulting in embodiments in which the PCB holds a video connection (MIPI DSI or HDMI) which can connect to the CM4 when fitted. The PCB video port may allow the connection of a Capacitive Touchscreen in some embodiments. The touchscreen performs the role of primary User Interface in these device variants. Such User Interface functions include, but not limited to, data entry, quality control information and triggers, Patient Information and User Login Credentials, workflow queues presentation and management, result reports display etc. While the touchscreen represents the primary User Interface to activate, engage and perform these tasks, the processing of such instructions and rendering of content displayed on the screen is handled by software loaded onto the CM4. In embodiments excluding a CM4, simpler instructions are managed by the Microcontroller Unit (MCU) located on the PCB. The MCU interfaces with a wired or wireless tether to another device (another PCB with a CM4 or a Cell Phone etc)—in this mode the MCU acquits tasks received from the other device and provides information to the other device-such that the other device takes on all of the functions detailed above for the touchscreen and the other device also performs many of the functions of the CM4 in the earlier embodiment (e.g. software, UI, network connection, sensor data storage, signal processing, report rendering etc. The exception being that the PCB's MCU retains direct instruction to the PCB hardware and also retains collecting ADC, environment and telemetric data before sending that to the other device.

The PCB may further comprise separate power module 904 to power the module and ground module 905 to prevent from surge voltages and short circuit etc. The PCB module may further comprise USB port 906 to receive and send data inputs and/or power, and LED indicators to indicate the power on and status of various subsystems.

The sample introduction device may be configured to introduce the sample to the sensing zone when the bound and unbound magnetisable particles are in each of a magnetised state and a fluidised state. Upon release of the magnetised state through the collapse of controlled electro/magnetic field so that Brownian motion of bound and unbound magnetised particles will once again become the dominant force acting upon the sample in the sensing zone.

Referring to FIG. 2, the sample introduction device 60 may be configured in a multiplex design. That is the sample introduction device may be used to sample and/or measure multiple biomarkers in controlled intervals from a single input sample. For example, the sample introduction device 60 may be designed with multiple sensor-aligned wells with magnetic beads functionalised to detect different angles from well to well. Thus, the sample introduction device 60 may be adapted to perform simultaneous detection of multiple analytes in a common sample body. Additionally or alternatively, the sample introduction device may be configured to perform simultaneous multiple detection of multiple samples of the same target.

The sample introduction device 60 may include one or more valves (not shown) that are controlled by control circuitry in the device. The one or more valves may be connected to each other.

The sample introduction device may be a microfluidic device or system.

The sample introduction device may comprise a sample well or reservoir. The sample to be analysed may be added directly to a sample well or microfluidic device without additional processing. The microfluidic system may comprise a fluid. The fluid may be selected from phosphate buffered saline (PBS). The phosphate buffered saline may comprise potassium phosphate dibasic (K₂HPO₄), sodium chloride (NaCl) and disodium phosphate (Na₂HPO₄). The PBS provides the continuous phase which the particles are suspended.

When an electric field sensor is used to detect the Brownian motion of the particles, the PBS provides the properties of having an impedance sufficiently different to that of the particles which allows differentiation by the electric field sensor of the particles vs the buffer fluid.

Microfluidic systems enable faster analysis and reduced response times. Microfluidic systems also offer the ability to automate the preparation of the sample, thereby reducing the risk of contamination and human error. Additionally, microfluidic systems require low sample volumes. Microfluidics may reduce diffusional distances by increasing the surface area to volume ratios, reducing reagent consumption through micro- and nanofabricated channels and chambers, and/or automating all steps of the process.

Microfluidic systems allows for miniaturisation which allows for lab-on-chip applications. Microfluidic systems may be used as part of the biosensor, for example, including channels for acquiring a biological sample (e.g., saliva and/or Gingival Crevicular Fluid and/or tears and/or sweat, etc.), processing the fluid (e.g., combining with one or more reagents and/or detecting an interaction with a biomolecule, etc.)

Microfluidic systems may be implemented in the form of microfluidic chips. Microfluidic chips comprise a set of micrometre or millimetre sized channels provided, for example by moulding or etching, onto a material or combination of materials such as glass, silicon, or other types of polymers. The microfluidic channels may be interconnected to form a network of channels. The channels may vary in length from millimetres to centimetres long.

The microfluidic chips may comprise one or more ports for receiving samples, and/or reagents. For example, the microfluidic chip may comprise sample inlet ports, and reagent ports.

The microfluidic chips may comprise a plurality of detection areas. The detection areas define portions of the channels in which detection and quantitation of the analyte or biomarkers in a sample occurs. The detection areas of the microfluidic chip correspond to the position of the magnetic sensors of the device such that when a microfluidic chip is placed over the detection surface of the device, each detection area vertically aligns with a corresponding magnetic/other sensor.

The detection areas may be located at any position along the channels. In some embodiments, the detection areas are located channel juncture points. That is, the detection area is located at the intersection of two or more channels.

The channel juncture points may comprise a reaction/detection well. The reaction/detection well may comprise a dimension that is larger than the channels.

The microfluidics may require some degree of sample preparation. The sample preparation may include cell lysis, washing, centrifugation, separation, filtration, and elution. In some embodiments the sample preparation is prepared off-chip. In an alternative sample preparation is prepared on-chip.

The microfluidic chip may be provided in a ‘ready to use’ format. For example, the microfluidic chip may be pre-loaded with all the necessary elements and cell separation (such as binder complex and reagents) for performing analyte detection and quantitation. That is, the ‘ready to use’ format only requires the addition of a sample to the microfluidic device.

The reaction/detection wells may be pre-loaded with binder complexes for binding one or more target analytes. The binder complex may be provided within a gel matrix in the reaction/detection wells. For example, each reaction/detection well may comprise hydrogel, agarose gel, or agar containing binder complexes. Binder complexes are described in detail later in the description.

The binder complexes and/or reagents may be added to the reaction/detection wells before use.

The microfluidic system may include hard or flexible materials, and may include electronics that may be integrated into the microfluidic chips. The electronics may include wireless communication electronics.

The microfluidic system may be a flow-through or stationary system. For example, the microfluidic system may comprise magnetic field or other sensors that are stationary relative to the microfluidic system.

The microfluidic system may operate passively. For example, the microfluidic system may operate under passive diffusion. That is, the microfluidic system does not require flow generated actively to perform effectively.

The microfluidic system may include a network of reservoirs, and that may be connected by microfluidics channels. The microfluidics channels may be configured for active metering or passive metering. This may allow for sample fluid to be drawn into the microfluidics channel and passed into a sample chamber.

The channels may be arranged in a cross-hatch configuration which is a multiplex design.

Alternately the channels may be arranged in a noncross-hatch configuration which is a parallel simplex design.

The microfluidic system may include microfluidic channels that are configured to allow access to various sample and/or detection regions on the device at various times. For example, the microfluidics device integrated into or on an aligner may be configured to provide timing via temporal-sampling of a fluid. For example, a microfluidic system can be designed to enable sampling with chronological order and controlled timing. In some variations, the timing of fluid within the microchannel may be timed actively, e.g., by the opening of a channel via release of a valve (e.g. an electromechanical valve, an electromagnetic valve, a pressure valve). Examples of valves controlling fluid in a microfluidic network include piezoelectric, electrokinetics and chemical approaches.

The channels of the microfluidic chip may comprise wicking structures. The wicking structures may improve the speed in fluid is transported by capillary action. The wicking structure may comprise porous media such as paper based material.

The microfluidic chip may comprise a plurality of microfluidics channels that are sequentially arranged. The fluid may be drawn into the microfluidics at a metered rate. The timing of access of samples to the channels may be staggered.

The microfluidics may carry out signal multiplexing. That is the microfluidics may be used to sample and/or measure multiple biomarkers in controlled intervals. For example, the microfluidics may be used to provide access to one or more sample chambers. The microfluidics may include one or more valves that are controlled by control circuitry in the device. The one or more valves may be connected to each other. Thus, the microfluidics may be adapted to perform simultaneous detection of multiple analytes in a common sample body. Additionally or alternatively, the microfluidics may be configured to perform simultaneous multiple detection of multiple samples of the same target.

The microfluidic channel(s) may have a cross section in the range of about 0.001 to 0.01 mm², 0.01 to 0.1 mm², 0.1 to 0.25 mm², 0.25 to 0.5 mm², 0.1 to 1 mm², 0.5 to 1 mm², 1 to 2 mm², or 2 to 10 mm², and useful ranges may be selected between any of these values.

In some embodiments the microfluidics receives a predetermined sample volume in the range of about 0.1 to 1 μL, 1 to 5 μL, 5 to 10 μL, 10 to 20 μL, or 20 to 50 μL or more, and useful ranges may be selected between any of these values.

Shown in FIG. 3 is an example of a sample introduction device/microfluidic chip. The microfluidic chip may comprise a plurality of channels arranged to direct the sample from the sample insertion area towards a detection area and functionalised particles for analyte detection.

The channels may have a cross-sectional dimension as mentioned above, and more preferably of about 0.01 mm² (0.1 mm×0.1 mm). The channels may have a variable length. For example, the channels may be 1, 5, 10, 15, 20, 25, 30, 35, 40, 45, 50, 60, 70, 80, 90, 100, 120, 140, 160, 180, 200, 250, or 300 mm long, and useful ranges may be selected between any of these values, (for example, from about 1 to 10, 1 to 20, 1 to 50, 1 to 100, 1 to 200, 1 to 300, 10 to 20, 10 to 40, 10 to 60, 10 to 80, 10 to 100, 50 to 100, 50 to 150, 50 to 200, 50 to 250, 50 to 300, 100 to 200, or 100 to 300 mm long).

The above dimensions of the channels facilitate passive capillary flow.

When in use, a sample is introduced to the microfluidics device via the sample insertion area. The sample insertion area may comprise an inlet port.

A filter membrane may be present at the insertion area 4 to separate and allow through the desired components of a sample. For example, to allow plasma from blood to pass into the microfluidic chip, but not cells. The presence of the filter membrane is dependent on the nature of the sample, and whether it comprises components for which it is desirable that they do not pass into the microfluidics chip.

Plasma-cell separation may result from on or of device configuration.

Once introduced into the insertion area, the sample will then contact the microfluidic channels and flow through the rest of the channel circuit.

The microfluidic system may be implemented as a lab-on-chip. The lab on chip may comprise of one or more magnetic sensors 3 in close proximity to the channels 2. For example, the microfluidic device 1 may comprise 1, 2, 3, 4, 5, 6, 7, 8, 9, 10, 12, 14, 16, 18, 20, 22, 24, 26, 28, 30 magnetic sensors arrayed around the microfluidic device 1.

The lab-on-chip may comprise two or more magnets, such as permanent magnets or electromagnets for example, arranged in close proximity to the channels that can be activated to draw magnetisable particles through the liquid in the channels 2 to enhance mixing. The mixing may, for example, be carried out for 1, 2, 3, 4, 5, 6, 7, 8, 9 or 10 min, and suitable ranges may be selected from between any of these values. The timing of mixing may depend on assay requirements such as sample volume, viscosity, composition and detection ranges of target analyte.

To effect mixing, the magnets (e.g. electromagnets) may be arranged at substantially opposed ends of a channel, or of the microfluidic device. For example, magnets may be controlled or switched such that they push/pull the magnetisable particles towards one end of a well/channel or the microfluidic device 1, and then the effect reversed to pull the magnetisable particles towards another end of the well/channel or the microfluidic device. This cycle may be repeated multiple times until the desired level of mixing has been achieved.

As will be appreciated by a skilled addressee in the field of endeavour, Brownian motion or Brownian diffusion may mean that the particles may move in any direction, including towards the magnetic field sensor or electric field sensor. The magnetic signal detected by the magnetic field sensor is based on the net movement of the bound and unbound magnetisable particles. The electric signal detected by the electric field senor is based on changes in impendence as the particles move through the continuous phase (e.g. the PBS).

When the bound and unbound particles are positioned in proximity to the magnetic or electric field sensor 40, the bound and unbound particles may locate at, or close to, the surface of wall of the sample well or sample reservoir until released. Once released from their proximity to the magnetic or electric field sensor 40, the particles may move, translationally or rotationally. Given their proximity to the surface of the sample well or sample reservoir immediately prior to release from the bias system, the bound and unbound magnetisable particles may typically first tend to move with an approximate 180° freedom of movement relative to the surface of the sample well or sample reservoir

The apparatus may comprise a biasing system configured to control the position of particles to be within the proximity of the sensing zone of the sensing module (such as sensors for detecting and measuring the particles). The biasing system may exert a force on bound and unbound particles within a sample such that the particles localise at a start position for detection/measurement by the sensing module. When the force exerted by the biasing system is relaxed or removed, the particles are released to undergo Brownian motion for detection by the sensing module.

The biasing system may comprise one or more biasing units.

The start position for detection/measurement by the sensing module may be a position where the particles are in their closest proximity to the detection unit.

The particles may be tethered or untethered. Tethered particles are tethered to larger secondary particles (macromolecules). Untethered particles may freely diffuse throughout the sample while tethered particles have limited diffusability and may freely diffuse in the sample within the range of the tether. Tethered particles are described in greater detail later in the specification.

In embodiments where the particles are untethered (i.e. freely diffusible in the sample), the closest proximity to the detection unit may be a position at the surface of a sample/reaction well adjacent to the detection unit. For example, the biasing system may exert a force to move freely diffusible bound and unbound particles in the sample/reaction well towards the surface of the microfluidic chip closest to the detection system.

In embodiments where the particles are tethered, the closest proximity to the detection unit may be a position closest proximity to the detection unit as permitted by the tethers.

The biasing system may comprise active or passive systems.

Active biasing systems uses energy from a power supply to generate a force that is used to position the particles within the sensing zone of the detection system. For example, active biasing systems may convert power from a battery to generate a magnetic field, an electric field, an acoustic wave, an electromagnetic wave, a pressure differential to cause the particles to localise at the start position for detection/measurement. Active biasing systems may comprise magnetic field generators, electric field generators, acoustic tweezers, centrifugation systems and active pumps.

Passive biasing systems may passively localise the particles within the sensing zone of the detection system without the need for external energy input. Passive localisation may be achieved using one or a combination of features (for example, on the microfluidic device) to localise the particles. For example, the passive biasing system may comprise a trapping element that localises the particles at the start position for detection/measurement by trapping the particles flowing in the microchannel of the microfluidic device. The passive biasing system may comprise other passive mechanisms such as capillary pumps.

Other biasing systems may include the use of soluble or dissolvable materials to locate or immobilise the particles, and the emulsions and liquid phase approaches for localising the particles.

The various biasing systems will be described in detail in the proceeding paragraphs.

The biasing system may comprise one or more magnetic field generators for generating an optimised magnetic field to magnetise the magnetisable particles and/or positioning the magnetisable particles in the microfluidic chip. The magnetic field generator may comprise magnets.

The magnetic field generators may generate a magnetic field in a direction perpendicular to the sensor. For example, the magnetic field generator may generate a magnetic from above and/or below the magnetic field sensors such that the magnetic field is perpendicular to the body of the magnetic field sensors.

The magnetic field generator may generate a magnetic field in a direction parallel to the sensor. For example, the magnetic field generator may generate a magnetic field from the side of the magnetic field sensors such that the magnetic field is parallel to the body of the magnetic field sensors.

The apparatus may comprise a combination of magnetic field generators that respectively generate magnetic field in perpendicular and parallel directions relative to the sensors.

The magnets may comprise electromagnets. The electromagnets may exert a field strength of about 0.5, 1, 5, 10, 15, 20, 25, 30, 35, 40, 45 or 50 Gauss, and suitable ranges may be selected from between any of these values.

The magnets may be controlled or switched on to position magnetisable particles into the detection area of the microfluidic chip and into close proximity to the magnetic sensors.

The magnets may exert a magnet field strength of about 0.01, 0.05, 0.1, 0.2, 0.3, 0.4, 0.5, 0.6, 0.7, 0.8, 0.9, 1, 5, 10, 50 or 100 Gauss, and suitable ranges may be selected from between any of these values.

In some embodiments the magnetisable particles have a particles size of about 1 to about 100 nm, and suitable ranges may be selected from between any of these values. The controller may bias the particles through the generation of an external force, the external force works to augment any inter-particle, particle-to-solvent or bonding forces.

In some embodiments the magnetisable particles have a particles size of about 0.5 μm to 5 μm, and suitable ranges may be selected from between any of these values. The controller may bias the particles through the generation of an external force, the external force works to fully counteract any inter-particle, particle-to-solvent or bonding forces.

The magnetic field generator may be configured to generate a magnetic field from below and/or above the detection surface.

The biasing system may comprise one or more electro-magnetic field (EMF) generators for generating an optimised electric field to position the particles within the sensing zone of the detection system. Electric field generators generates an electrical field across the sample to move the particles in the sample. The EMF generator may comprise a power supply unit, or any form of a rotating armature AC generator, such as a stator or a rotating field AC generator, such as a rotor, or poly-phase generators.

The power supply unit may be a DC power supply unit.

The electric field generator may output a voltage of about 0.1, 1, 2, 3, 4, 5, 6, 7, 8 or 9 Volts, and suitable ranges may be selected from between any of these values.

The electric field generator may output a wattage of 100, 120, 140, 160, 180, 200, 220, 240, 260, 280, 300, 320, or 340, 360, 380, 400, 420, 440, 460, 480, 500 watts, and suitable ranges may be selected from between any of these values.

The electric field generator may comprise sensing elements, for example, electrodes (anodes and cathodes), conductive coils, and conductive circuits. For example, cathodes and anodes may be provided to the sample well.

The electrodes may be operated at an Alternating Current (AC) current frequency of 10, 100, 1000, 10000 kHz.

The electric field generator may be configured to generate an electric field besides, above or around the detection surface.

The device may comprise of one or more electric field generators for generating an electric field to facilitate Di-eletrophoresis (DEP).

The electric field generator may comprise of one or more pairs of electrodes.

The electrodes may be operated with Direct Current (DC) or Alternating Current (AC), at voltages of 1, 2, 3, 4, 5, 6, 7, 8, 9 or 10 volts.

The electrodes may be operated at an Alternating Current (AC) current frequency of 10, 100, 1000, 10000 kHz.

The electrodes may be controlled or switched on to position particles into the detection area of the microfluidic chip and into close proximity to the detection surface.

The electric field generator may be configured to generate an electric field besides, above or around the detection surface.

In some embodiments, the biasing system may be implemented using di-electrophoresis. A biasing system based on di-electrophoresis controls the movement of particles using non-uniform electric fields via electrodes. The frequency of such a non-uniform electric fields may be set to control and position particles within the fluid of a particular size and shape.

The biasing system may be based on acoustic, cavitation, vibration, or acoustofluidics.

The biasing system may comprise one or more acoustic or electric tweezers for generating acoustic waves to position the particles within the sensing zone of the detection system. Acoustic tweezers use acoustic waves or sound radiation forces to move particles within a sample. For example, Standing Surface Acoustic Wave(s) (SSAW) through the application of Interdigital Transducers (IDT) (may be arranged orthogonally) to focus particles within the sensing zone of the sample introduction device.

The sample introduction device such as a microfluidic device may be designed with specific features (such as the shape and dimension of the microchannels) that optimise the effectiveness of the SSAW generated by the IDT. For example, the sample introduction device may comprise pressure nodes.

The biasing system may be implemented using Piezo effect. Piezo films, membranes, or reflectors may be used to localise particles at the start position for detection/measurement by the sensing module within the sensing zone.

The sample introduction device may incorporate acoustic vortex designs and features that enhance localisation of the particles within the sensing zone. Vortices may be generated through combination of actuation, flow rate, holographic transducers, microfluidic lens features to control vortex forces to very fine degrees of motion.

The biasing system may comprise a centrifugal system for positioning the particles within the sensing zone of the detection system using centripetal force. In this embodiment, the sample introduction device (such as a sample receptable or microfludic chip) may be centrifuged at a suitable speed and for a suitable amount of time to localise the particles within the sensing zone.

When a centrifugal system is used, the sample introduction device may comprise a sample receptacle having one or more channels with a circular or semi-circular cross-section. The channel of the sample receptacle may comprise a radius of about 10, 15, 20, 25, 30, 35, 40, 45, 50 mm, and suitable ranges may be selected from between any of these values.

The sample introduction device containing a sample may be centrifuged at a speed of about 100, 150, 200, 250, 300, 350, 400, 450, 500, 550, 600, 650, 700, 750, 800, 850, 900, 950, or 1000 rpm, and suitable ranges may be selected from between any of these values.

The sample introduction device containing a sample may be centrifuged for a predetermined time of about 0.5, 0.75, 1, 1.25, 1.5, 1.75, 2, 2.25, 2.5, 2.75, 3, 3.25, 3.5, 3.75, 4, 4.25, 4.5, 4.75, 5, 5.25, 5.5, or 6 minute(s), and suitable ranges may be selected from between any of these values.

For example, the sample introduction device containing a sample may be centrifuged at 520 rpm for 4 minutes and 15 seconds.

After centrifugation for the predetermined amount of time, the sample introduction device may be decelerated to a stop over a period of time. For example, the centrifuge may be decelerated over a period of 1, 2, 3, 4, 5, 6, 7, 8, 9, 10, 11, 12, 13, 14, 15 seconds.

Once completely stopped, the sample receptacle remains stationary throughout the remainder of the detection and measurement. Sensors are positioned to be in close proximity of the circular channel (at the outside circumference) to perform the detection and measurement.

The biasing system may comprise laminar flow including laminar flow patterning and micromixer. This may be implemented as a Pinch Flow Fractionation (PFF) using microfluidic features, micro-bubblers and other complementary design elements or inclusions. Additional microfluidic design features may be utilised to interrupt the laminar flows or otherwise trigger the release of particles to the forces of diffusion (including Brownian Motion).

The biasing system may comprise an active pump or suction system. The active pump or suction system may be implemented in conjunction with a trapping element provided to the sample introduction device.

In some embodiments, the trapping element may be provided in a sample well or microchannel of a microfluidic device to capture the particles. The trapping element may be positioned at locations in the sample introduction device that correspond to the sensing zone of the sensing module. The trapping element may comprise permeable or semi-permeable material that allows sample fluid to pass through while retaining the particles. For example, the trapping element may comprise a gel such as agarose gel.

In some embodiments, agarose gel may comprise a 0.5, 0.75, 1, 1.25, 1.5, 1.75, 2, 2.25, 2.5, 2.75, 3% agarose gel, and suitable ranges may be selected from between any of these values.

In some embodiments, the trapping element may comprise an angled ramp.

The pressure or suction generated by the active pump or suction system forces the particles to become trapped in the trapping element located in close proximity of the sensing module. When the pressure or suction is relaxed or removed, the particles are free to undergo Brownian diffusion which is detected and measured by the sensing module.

The active pump or suction system in combination with the sample introduction device may be configured to create hydrodynamic effects such that freely moving particles become trapped in recirculating flows to localise the particles in close proximity to the sensor.

The active pump may be actuated in cycles of active flow and passive flow. In each cycle, the active pump may be actuated for a predetermined time to establish active flow and deactivated to allow for predetermined period of passive flow. For example, the active pump may be actuated for about 1, 2, 3, 4, 5, 6, 7, 8, 9, or 10 second(s) and deactivated for period of about 5, 6, 7, 8, 9, 10, 11, 12, 13, 14, 15, 16, 17, 18, 19, or 20 seconds, and suitable ranges may be selected from between any of these values.

The active pump is actuated for 1, 2, 3, 4, 5, 6, 7, 8, 9, or 10 cycles before the sensing module acquires data.

The biasing system may comprise a passive pump configured to passively localise the particles within the sensing zone of the detection system without the need for external energy input. The passive pump may be any microfluidic design feature that enhances and/or controls capillary effect without the need for an active pump.

The passive pump, such as a capillary pump, may be implemented using microfluidic design features which enhance the capillary effect within the microfluidic chip such that the sample fluid may be passively-drawn through a trapping element (described in relation to the active pump) to position the beads in close proximity to the sensor.

The passive pump may be tuned to a set amount of time in view of the controlled hydrodynamics of the microfluidic design such that after a set amount of time, the capillary effect is broken by the lead fluid entering a relatively larger chamber within the microfluidic (or other design examples).

The particles may be embedded in or immobilised on soluble or dissolvable materials. The particles may be embedded in or immobilised at locations in the sample introduction device that correspond to the sensing zone of the sensing module.

The particles may be embedded or immobilised such that the surface of the particles remains available for binding target analytes in a sample. Such functionalised particles may be loaded into sample introduction device in a dry state and utilising one of any applicable adhesive compounds known to dissolve in liquids. For example, the introduction of a sample (such as plasma) dissolves the soluble or dissolvable material to release the particles which undergo Brownian motion that is detectable and measurable by the sensing module.

The soluble or dissolvable materials may have biodegradable and biocompatible qualities.

The soluble or dissolvable materials may comprise soluble chemicals, reagent films, and adhesives including but not limited to sodium alginate, calcium alginate, gelatin, agar, agarose, latex adhesives, hydrogels, cellulose membranes, polyvinyl alcohol etc.

The biasing system may be based on emulsion and liquid phase approaches such as Pickering emlusions. According to such an approach, particles may be transported using an emulsion that is controllable to revert into the liquid phase via changes in pH, temperature, and/or ionic strength. The particles may be transported in the emulsion to be in close proximity to the sensing module and then be released through a reversion from emulsion phase to liquid phases by a controlled change in one or more of the known triggers to drive such a phase shift. Once the emulsion has reverted to liquid phase the beads will be under the influence of Brownian motion etc allowing for the sensor to detect the same.

Where appropriate, one or more of the aforementioned biasing systems may be used in combination to achieve an enhanced biasing effect. For example, the magnetic generator may be used in combination with an active pump and suction system to achieve enhanced effect.

The orientation detection module may comprise a sensor for detecting an orientation of the apparatus. The sensor for detecting orientation may comprise gyro-scope based sensors, an inertial measurement unit, and/or an accelerometer. The sensors enables the apparatus to operate in any orientation. The operation of the apparatus or performance of the present method is not dependent on gravity to function effectively. That is, the apparatus can perform the present method regardless of how the apparatus is orientated. For example, the apparatus may be operable in an inverted configuration where the magnetic field sensor is orientated above the sample reservoir or microfluidic device.

Referring to FIG. 12, the orientation detection module 1200 of the apparatus is illustrated. In an embodiment, the orientation detection module comprises accelerometer 1201 configured to detect the orientation of the apparatus.

The power management module may comprise an onboard power supply controller to control/power to the apparatus. The power supply may be an AC input and/or a DC input.

The power control module may allow the device to select power sources to minimise signal noise and to maximise performance. For example, AC power (supplied by the USB-C input) whenever available expect when the magnetic sensors are reading/sensing, and during such times, the DC power battery is utilized temporarily,

The AC input could include receiving power externally from a USB type-C based connection provided on the apparatus.

The onboard DC input power supply may comprise a rechargeable lithium-ion battery. In some embodiments, the power supply is a 3.7v, 1200 mAh, lithium-ion battery.

In an embodiment, the power management module may comprise power rectifiers and/or boost regulators to rectify the voltage (from 3.3 V to 5 V).

In an embodiment, the power management module may comprise regulators to maintain the power at 3.3V.

The power management module may comprise a switching unit to switch from AC to DC mode if external power is not available.

The power management module may further comprise a battery status indicator to determine and indicate the power level in the battery in case external power is not available.

The power management module may comprise a battery charge percentage reference in the user interface.

The power management module may provide a quality control reference at the attempted commencement of each test to determine whether sufficient power remains within the battery to complete each test.

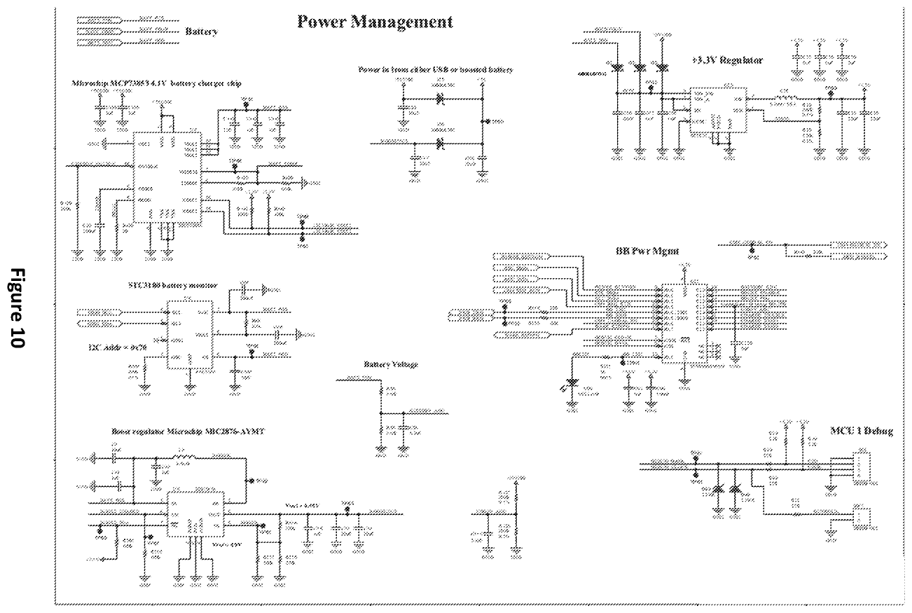

Referring to FIG. 10, the power management module of the apparatus is illustrated. The power management module 1000 comprises a power management unit 1005 configured to determine whether there is an incoming power of 5V received via a USB connector. If this power from the USB connector is detected, then the battery charger chip 1001 is configured to charge an internal battery. If the incoming power is not detected, then the power is received from the internal battery.

The booster circuit 1002 within this module is configured to boost the voltage of the battery. In an embodiment, the battery monitor circuit 1003 is configured to determine the power level of the battery. The power management module also comprises a voltage regulator 1004 to power certain low voltage components of the apparatus. For example, the components operating at 3.3V input range.

The control module may comprise a controller. The controller may be connected to the apparatus to receive signals from the array of magnetic field sensors 40 or electric field sensors 50 which represent relative net changes in magnetic or electric fields of the bound and unbound magnetised particles induced by their Brownian motion or diffusion.

The controller may be configured to determine a relative amount of the analyte in the sample based on the signals received from the array of magnetic or electric field sensors.

The wireless communication module may comprise a wireless communication and/or a cellular communication modules. The wireless communication module may be configured for wi-fi and/or Bluetooth low energy wireless communication. The cellular communication module may be configured for 3G, 4G, and/or 5G cellular communication.

The communication module may facilitate communication of the apparatus with one or more external networks or devices including other PCB cores within the same core (e.g., multi-core design embodiments). In some embodiments, the apparatus may wirelessly connect with a computer or a mobile communication device. In some embodiments, the apparatus may be connected to an internet of things (IoT) network.

In an embodiment, the communication module configured to wirelessly transmit telemetric, environmental and diagnostic data obtained on the sample to another networked device.

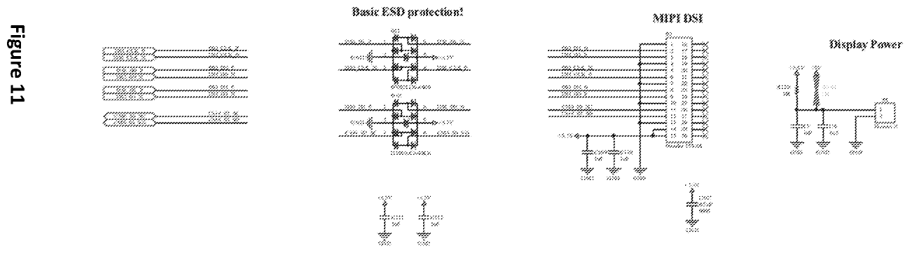

The apparatus may comprise an integrated display. Illustrated in FIG. 11 is the display module 1100 comprising an input module 1101 configured to send and receive signals and information instructions from the CM module. The display module may comprise ESD protected circuit 1102 and feeding the signals from the ESD-protected circuit to the integrated display 1103.

The internal quality control steps of the apparatus will now be presented below. The apparatus may initiate a series of internal Quality Controls (QC) once the apparatus has powered up (PCB switch/remote switch/timed power-on/Accelerometer Sensor/Remote Instruction from a Networked Core or Device) The QC controls may include confirming which Sensor Positions are populated on the PCB, Health and Status of Device Systems, Components, Error Conditions (such as high-G force events since last power on which may indicate potential structural damage for example) prior to Cycling through Test Parameters across all sub-systems, Reading Ambient Conditions such as device temperature, ambient magnetic fields above sensors, Set & Reset of all sensors and utilising sensors on different Set-Reset modes to measure then record for potential Algorithm offset any system generated interference or bias.

Following the QC checks the signal generation may occur in the following steps:
Input/Software/Firmware (local or remote) instructs action.
   In some embodiments this may include input data from a connected Core (PCB), Mobile Phone or from a Near Field Communication tag with embedded data. The NFC tag could come from a single-use NFC tag included in a disposable Diagnostic Chipset and provide information for the system to utilise in terms of analysis, Biomarkers, Sensor locations, Normal Sensitivity ranges for results, Batch Numbers, Use-By-Dates, Relevant Species, Relevant Fluid Type (blood, tears, saliva, etc), Need for Electromagnet(s), Assay type, Analyte Binding Kinetics and wait time, Read Cycles, Frequency, Duration, Mathematical Confidence intervals, Accept-Extend-Failover test values. This process will likely be performed in the background during log-in/customer/patient details being selected.
Software/UI/Indicators may instruct the user to insert the microfluidic/sample.
   The Software may be configured to integrate any input instructions in the form of UI/indicators and commences related sequence of actions on PCB and attached peripherals (Battery/USB C/Indicator LEDs/Screen/Coils etc).
   Depending on Assay (embodiment) electro-magnetic field generators (electromagnets) may be powered and follow a pre-ordained sequence of On/Intensity Curves/Off/potential Polarity Switches, and Potential repetitions. These may control the magnetic particles for optimised performance and rapid binding kinetics of analyte to functionalised magnetic beads. In some embodiments, the electromagnets and their generated fields may be controlled and optimised for fast reaction times using power control circuits e.g. H-bridge circuits. In some embodiments, a further quality control test may be performed by using existing sensors to determine environmental changes synchronised to sample introduction into the device, so that liquid movement, location, speed and viscosity can be determined. After a minimum pause >10 μs (to ensure the device is not reading Neel relaxometry) the sensors may be quickly set/re-set (to ensure absolute chronological alignment or magnetic set-re-set) in quick succession after the set-reset, several millionths of a second later the analogue Magnetic Field sensors are read as up to an aggregate 450,000 reads per second (across a 24 array of sensors). This occurs via the following approach; within each Field Sensor the analogue dynamic magnetic field environment is continually sensed and converted into a voltage and fed to a sensor-dedicated 10,000× amplifier. All sensor to dedicated amplifier circuits are at/near to equidistant in length to ensure data parity and timing). The amplifier then feeds that (amplified voltage signal) to one of three Analogue to Digital Converters which polls the data at 16 Bit resolution. Depending on required/desired read times and number of read cycles, tens of millions of datapoints per chip for processing in under a minute.

Between either each read or some other number of reads, the sensors may be set/reset to maintain maximum consistency and data integrity. For this same reason, data circuits are protected by ground plane circuit layers above and below the data circuits—this to minimise any interference and preserve maximum signal relevance. The ADC's progressively stream/send the data to either the MCU or the CM for processing, storage, forward sending such as to a connected device or mobile phone. The active data analysis is performed such that a feedback loop is created in which data acquisition can be actively extended or concluded depending on clarity, quality, consistency, clarity etc of the data read and processed against device parameters (including parameters from the elemetric, environmental viscometer, Near Field inputs, QC checks, temperature etc).

In an embodiment the apparatus comprises an enclosure for housing at least one circuit board. The enclosure may further comprise an integrated display configured to render a status and/or diagnostic output obtained from the circuit board.

In an embodiment, the enclosure comprising the integrated display and at least one circuit board is configured to perform the operation of a lab-on-a-chip device. In another embodiment, the enclosure comprising the integrated display and a plurality of circuit boards being arranged in parallel is configured to perform the operation of a lab-on-a-bench device.

In an embodiment the enclosure performing the operations of the lab-on-a-chip and lab-on-a-bench device is configured to be controlled by a user interface.

This enclosure/case may have minimal openings, presents a uniform surface which is easily sanitised, retaining the sample outside the device (any portion entering the device being on a fully encapsulated in plastic in the sample introduction device and in close proximity to the sensor surface. The apparatus may be configured for either a benchtop mode (screen facing up at a small angle) or a wall-mount mode (screen facing outward at a small angle) operation. The entry point for the sample introduction device may be adjusted/reoriented between these two implementations.

In Veterinary clinical rooms, the Wall mount embodiments may solve the issues arising from the animals tending to knock over anything on a bench or desk, where fluids often meet items in these same locations).

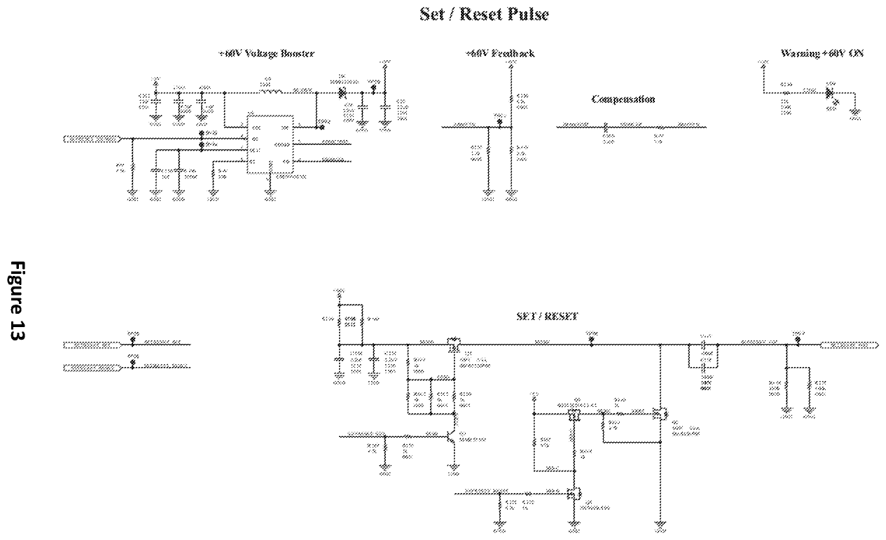

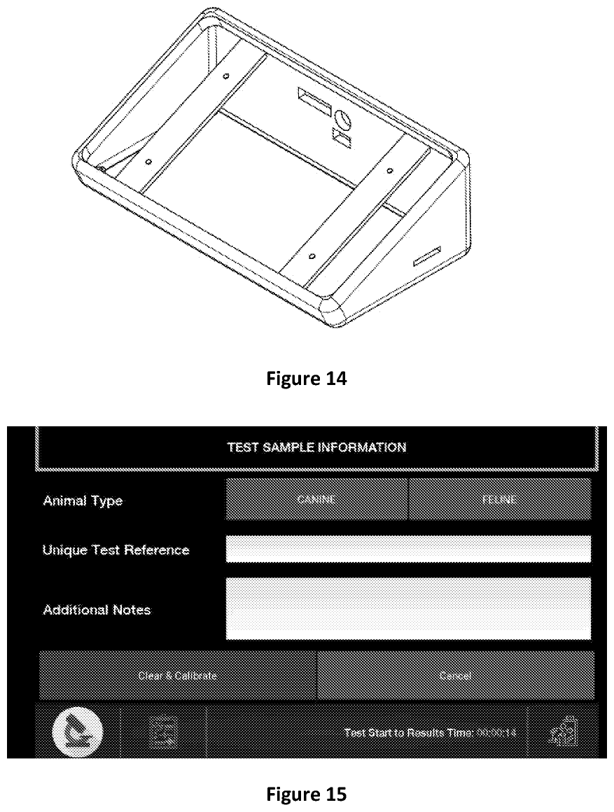

Referring to FIG. 14 the CAD designs of a variant of the apparatus are displayed. In this embodiment, the enclosure is shown in a curved-corner rectangular aperture on the upper side to accommodate a seven inch capacitive touchscreen). In some embodiments, this screen represents the primary user interface through onboard software on the apparatus or a tethered device. A number of variants of the apparatus embodiment is presented below.

The apparatus may comprise a single core having a single compute module. The apparatus may comprise a case, screen, battery, and optionally passive or active cooling. In this embodiment we may position the sample entry point on the left or the right or in the centre front. This device may autonomously manage its one UI, network and diagnostic functions and QC process. It will be appreciated that smaller versions may be implemented for more mobile applications such as mobile veterinarians, at home testing by patients and owners with results being returned to clinics/veterinarians and emergency implementations for critical presentations at hospitals and veterinary reception.

The apparatus may have a larger capacity, comprising a case, screen, battery, optionally passive or active colling, and a core having two compute modules including optionally a separate, dedicated compute unit. In this embodiment the separate dedicated compute unit may handle power output to the cores, data I/O to the cores, UI to the screen and also network connection/workflow queues and communication to practice management software. The cores (without a compute module) may operate as slaves to the central unit, drawing power and data through the usb-c connection simultaneously. In other embodiments, such as using cat5/6 connection cables, the cores may stream their raw results to the compute unit for calculation and report rendering and networked/screen presentations modes. These implementations may either have front facing left and right located chipset apertures or left side of case and right side of case apertures. The large capacity implementations may be configured to be suitable for smaller veterinary in-house laboratories and shared/multi-animal clinical rooms (plus human analogues being small GP clinics etc).

The above device variants are expected to fit within enclosure dimensions similar to one another and similar to FIG. 14, and are configured for diagnostic testing using peripheral blood pricks or systemic blood samples.

FIG. 15 illustrates an embodiment of the touch screen user interface of the apparatus (in the lab-on-a-chip or lab-on-a-bench setting) used in a veterinary setting. In this embodiment, the user (veterinarian or a laboratory clinician) may input data in relation to the sample being processed. In this instance, the user can select between whether the sample belongs to a canine or a feline and add any additional notes on the test (for e.g., patient information in relation to the animal). A unique test reference is then presented to the sample being run, which can later be retrieved during analysis of the results.

In some embodiments, the device may include network and workflow integration to practice management software and applications. This may allow for remote ordering of tests and integration of results within the practice (Human or veterinarian) software systems and platforms.

In non-networked embodiments/configurations, the controller is configured to render a graphical image of the results of the diagnostics on in the screen and in a datafile. This can include environmental and various telemetry metrics of the apparatus during its operation. This information may then be transmitted to a nominated email or a cloud storage source (with the input Reference Numbers, Patient Name and Details as entered immediately prior to the test commencing).

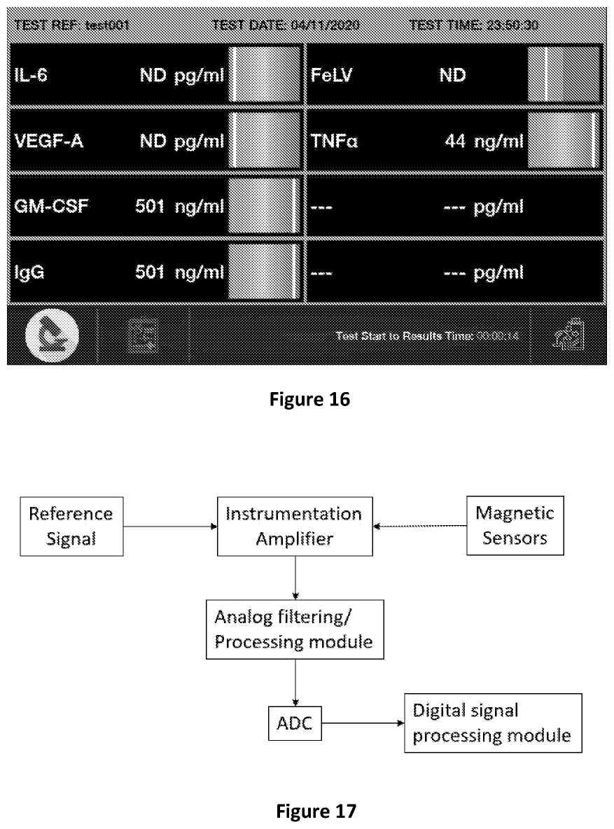

FIG. 16 illustrates an instance of the example user interface of the apparatus depicting the diagnostic results of the processed sample devices.

The apparatus may be configured to be operated as a personal health assistant. In an embodiment, the apparatus may be connected to any one of personal assistant devices such as Amazon Echo, Google Nest, Apple Watch, or any smart devices using virtual assistants such as Microsoft Cortana, Amazon Alexa, or Apple Siri.

The apparatus may be integrated or connectable to the personal assistant devices. Such an embodiment enables the sharing of one or more components between the apparatus and the personal assistant device. For example, an integrated personal assistant device may utilise the processing power, memory, network connectivity, cloud storage, power supply of the apparatus, or vice versa.

Integration of the apparatus and personal health device enables an enhanced integration of contextual health data and services such as Telehealth appointments and platforms, real-time Telehealth prescription of diagnostic panels, online pharmaceutical fulfillment, fitness and wellbeing data and programs relevant to diagnostic results, Telehealth professionals' advice, voice control and remote authorisation of the device, and HIPAA approved medical record apps.

Integration of the apparatus and personal health device enables a holistic approach to healthcare by providing a contextual benefit of health or medical data whilst providing the at-home diagnostic required for a full suite of remote-healthcare or preventative healthcare services.

The apparatus may be backward-compatible with older devices. Such an embodiment, would allow connectivity to larger population of devices to expand access to remote populations as well as expanding healthcare options for population centres, particularly during periods of limited social mobility.

The virtual assistant may be built-in to the apparatus.

The apparatus may be configured to provide alerts, reminders and set targets and schedule appointments with a medical professional to discuss the results of the diagnosis.

Described is a method for detecting an analyte in a sample, comprising the steps of:
bringing a sample comprising a target analyte into contact with particles that generate or be induced to generate a detectable signal, the particles being coated with binding molecules complementary to the target analyte resulting in bound and unbound binder complexes,
applying a biasing field to position the particles, comprising both bound and unbound binder complexes, in proximity to a sensing module (the ‘capture’ step),
changing the biasing field sufficient to release at least a portion of the particles, comprising both bound and unbound binder complexes, from their proximity to the sensing module (the ‘release’ step), and
measuring changes in the detectable signal detected from the particles as a result of the net movement of the particles relative to the sensing module. The movement is either translational and/or rotational movement.

The method described is based on the concept of bringing the particles that generate or be induced to generate a detectable signal and analyte complex into close proximity with a sensing module (i.e. either magnetic or electric field sensor). The biasing field strength is modulated to allow the particles and analyte complex to diffuse away (i.e. by translational and/or rotational movement) from the magnetic or electric field sensor. The sensing module then measures changes in the detectable signal generated by the particles over time due to Brownian movement or diffusion that allows quantification of the amount of particle-analyte complexes, which then allows the amount of analyte to be determined in the sample. That is, the bound and unbound binder complexes are distinguished based on their diffusion characteristics, as determined from the net flux values read by the changes in the sensing module over time. The particles (i.e. both the bound and unbound complexes) physically move relative to the sensing module so that the bound and unbound complexes can be distinguished (given they will move to a differing degree due to different diffusion characteristics).

Broadly stated there may be three stages in the method of analysing a sample. The first stage may be a pre-sample baseline sensing stage. This stage is carried out to obtain a baseline reading without the sample present. The baseline reading provides a base comparison for the subsequent sample reading. The pre-sample baseline sensing stage may take 1, 2, 3, 4 or 5 seconds, and suitable ranges may be selected from between any of these values, (for example, about 1 to about 5, about 1 to about 4, about 2 to about 5, about 2 to about 3 or about 3 to about 5 seconds).

A second stage may be loading the sample into the device. This stage may include sample mixing and analyte-to-binder complexing (i.e. where the functionalised particles bind to the analyte). This stage may take around 3, 4, 5, 6, 7 or 8 minutes, and suitable ranges may be selected from between any of these values, (for example, about 3 to about 8, about 3 to about 7, about 3 to about 5, about 4 to about 8, about 4 to about 6 or about 5 to about 8 minutes).

A third stage may be the sample read stage. That is, the particles are positioned in proximity to a sensing module, the biasing field is changed to release at least a portion of the bound and unbound binder complexes, and the sensing module measures changes in the signal detected from the particles as a result of their net movement relative to the magnetic sensor. This stage may take around 1, 2, 3, 4, 5 or 10, 11, 12, 13, 14, 15, 16, 17, 18, 19 or 20 seconds, or 30, 31, 32, 33, 34, 35, 36, 37, 38, 39, 40, 41, 42, 43, 44, 45 seconds, and suitable ranges may be selected from between any of these values, (for example, about 10 to about 20, about 10 to about 18, about 10 to about 15, about 11 to about 20, about 11 to about 19, about 11 to about 16, about 11 to about 15, about 12 to about 20, about 12 to about 18, about 12 to about 15, about 13 to about 20, about 13 to about 19, about 13 to about 17 or about 13 to about 15 seconds).

The particles may be attached to other objects such as larger secondary particles or molecules. The magnetisable particles may also be attached to surfaces. Attachment to other objects or surfaces allow the magnetisable bead to be positioned at a specific location whilst retaining the ability to undergo Brownian diffusion (within the limits of the attachment or tether) that is detectable and measurable by the apparatus.

The tethering advantageously allows retains the ability for the particles to undergo Brownian diffusion whilst being localised as a specific location in a larger shared volume, and as such, multiple types of magnetisable particles (types by analyte recognition or other properties) can all be in their discrete locations (e.g. aligned to a specific magnetic sensor) whilst in a shared volume, and this allows for multiplex detection of different target analytes in the one volume.

Tethering to the non-magnetisable beads or surfaces of a microchannel allows for this multiplex detection as the non-magnetisable bead can act as an ‘anchor’ to keep the tethered particles in a location via a combination of size, surface chemistry and interaction with its local environment.

For example, magnetisable particles may be molecularly tethered to a larger non-magnetisable particle such as a latex bead such that the magnetisable particles are localised in a specific area due to the larger non-magnetisable bead but may still freely diffuse within the limit of the tethers. In another example, the magnetisable particles may be molecularly tethered to a surface, such as a surface of the microfluidic device corresponding to sensing zone of the sensing module.

The non-magnetisable particles may comprise any suitable non-magnetisable particles, including but not limited to, latex beads, polystyrene beads, or other types of polymer beads.

In some embodiments, non-magnetisable particles such as latex beads with surface chemistries (such as amines and carboxyl groups) can have molecular tethers attached to them (e.g. Polyethylene glycol-PEG) such that one end of the molecular tether is attached to the latex bead (with chemistries compatible with the latex bead surface) and the other end is attached to the magnetisable bead (with chemistries compatible with the magnetic bead surface e.g. Biotin on the tether attaching to Streptavidin on the surface of the magnetic bead), thus forming a tethered connection between the two beads.

The molecular tether may be about 5, 10, 15, 20, 25, 30, 35, 40, 45, 50, 55, 60, 65, 70, 75, 80 nm in length. As stated above, the amount of analyte in a sample is determined based on the change in the signal detected by the sensing module. The sensing module detects the change based on the net movement of the particles. Once released from their proximity to the sensing module the particles, comprising both bound and unbound binder complexes, will move away from the sensing module. This movement will be random based on Brownian diffusion.

Typically, the sensing module is located close to or adjacent (on the non-sample side) to the surface of the sample well or sample reservoir. When bound and unbound particles are positioned in proximity to the magnetic field sensor, the bound and unbound particles may locate at, or close to, the surface of wall of the sample well or sample reservoir until released. Once released from their proximity to the sensing module, the particles may move, translationally and/or rotationally. Given their proximity to the surface of the sample well or sample reservoir, the bound and unbound particles may typically move with an initial approximate 180° freedom of movement relative to the surface of the sample well or sample reservoir. Brownian diffusion means that the particles may move in any direction, including towards the magnetic field sensor. The magnetic signal detected by the magnetic field sensor is based on the net movement of the bound and unbound particles.

Benefits of the present invention may include rapid detection (for example see Example 2) and a highly sensitive detection methodology (for example, see Examples 1 and 3).

When considering the encounter between the analyte and the particle that are free in solution, the diffusional encounter step can be split up into (1) the process of diffusional transport through the fluid volume, and (2) the process of near-surface alignment. Where volume transport generates the first encounters between particles and target analyte, the subsequent near-surface alignment process deals with the alignment rate of the binding sites of the reactants. The volume transport is essentially a translational process, while the alignment is determined by both the translational and the rotational mobility of the reactants.

When the free components react in solution, the alignment process (i.e. rotational diffusion) is an important restriction due to the highly specific alignment constraints, but volume transport (i.e. translational diffusion) is not a limitation. In the case when one of the components is attached to a surface, volume transport can become a limitation.

The magnetic properties of nano- and micron-sized magnetic materials differ from those of the corresponding bulk magnetic materials. Typically, magnetisable particles are classified as paramagnetic, ferromagnetic, ferrimagnetic, antiferromagnetic, or superparamagnetic based on their magnetic behaviour in the presence and absence of an applied magnetic field.

Diamagnetic materials exhibit no dipole moment in the absence of a magnetic field, and in the presence of a magnetic field they align against the direction of the magnetic field.

Paramagnetic particles exhibit random dipole moments in the absence of a magnetic field, and in the presence of a magnetic field they align with the direction of the magnetic field.

In perpendicular magnetic fields, the superparamagnetic particles may repulse from one another whilst exhibiting aligned magnetic moments. This will increase the equilibrium spacing and reduce correlated particle movement.

Parallel magnetic fields may create an attraction between the superparamagnetic particles in equilibrium and exhibit a higher degree of correlated particle movement.

Ferromagnetic materials exhibit aligned dipole moments.

Ferrimagnetic and antiferromagnetic materials exhibit alternating aligned dipole moments.

In one embodiment the magnetisable particles are paramagnetic particles. Such particles will become magnetic when subjected to a magnetic field. Once the magnetic field is removed, the particles will begin to lose their magnetic characteristics.

In an alternate embodiment the magnetisable particles are ferromagnetic particles. That is, they always exhibit magnetic characteristics regardless of whether subjected to a magnetic field.

Commercially available magnetisable particles include Dynaparticles M-270, Dynaparticles M-280, Dynaparticles MyOne T1, and Dynaparticles MyOne C1 from Thermo Fisher Scientific, pMACS MicroParticles from Miltenyi Biotec, SPHERO™ Superparamagnetic Particles, SPHERO™ Paramagnetic Particles, and SPHERO™ Ferromagnetic Particles from Spherotech.

In one embodiment, the magnetisable particles used are Spherotech SVFM-20-5 (2.0-2.9 micrometer).

The magnetisable particles may be ferromagnetic particles coated with Streptavidin. The ferromagnetic particles coated with Streptavidin may be functionalised with biotinylated “detection” antibodies.

The magnetisable particles may be formed by ferrites which are themselves formed from iron oxide (such as magnetite and maghemite). Various methods are known for synthesising iron oxide and metal-substituted ferrite magnetisable particles such as co-precipitation, thermal decomposition, and hydrothermal. Co-precipitation processes use stoichiometric amounts of ferrous and ferric salts in an alkaline solution in conjunction with a water-soluble surface coating material, such as polyethylene glycol (PEG), where the coating provides colloidal stability and biocompatibility. The size and properties of the magnetisable particle can be controlled by adjusting the reducing agent concentration, pH, ionic strength, temperature, iron salts source, or the ratio of Fe²⁺ to Fe³⁺.

The size and shape of magnetisable particles can be tailored by varying the reaction conditions, such as the type of organic solvent, heating rate, surfactant, and reaction time. This method leads to narrow size distributions of the magnetisable particles in the size range 10 to 100 nm. Fe²⁺ may be substituted by other metals to boost the saturation magnetisation.

We have also found that larger particles may be effective. For example, the particles may have a size of about 0.5, 1, 1.5, 2, 2.5, 3, 3.5, 4, 4.5, or 5 μm, and suitable ranges may be selected from between any of these values.

The magnetisable particles may be coated with a hydrophobic coating during the synthesis process. If so, then the method of manufacturing the magnetisable particles may include an additional step of ligand exchange so that the magnetisable particles can be dispersed in water for further uses.

The magnetisable particles may be manufactured by polyol-hydrothermal reduction which produces water-dispersed magnetisable particles in the size range from tens to several hundred nanometres. The size and surface-functionalisation of the iron oxide magnetisable particles may be optimised by adjusting the solvent system, reducing agent, and type of surfactant used. This process may be used to synthesise FePt magnetisable particles.

The magnetisable particles may be manufactured by a reverse water-in-oil micelle methodology. This method forms a microemulsion of aqueous nanodroplets of iron precursors that is stabilized by a surfactant in the oil phase with the magnetic nanoparticles obtained by precipitation. Iron oxide nanocrystals may be assembled by combining the microemulsion and silica sol-gel, which may be obtained via co-precipitation into magnetisable particles having a diameter of more than 100 nm.

Metallic magnetisable particles may be either monometallic (e.g., Fe, Co, or Ni) or bimetallic (e.g., FePt and FeCo). Alloy magnetisable particles may be synthesised by physical methods including vacuum-deposition and gas-phase evaporation. These methods may produce FeCo magnetisable particles with high saturation magnetisation (about 207 emu/g) and may be synthesised via the reduction of Fe³⁺ and Co²⁺ salts.

The magnetisable particles may comprise a single metallic or metallic oxide core. The magnetisable particles may comprise multiple cores, multilayers of magnetic materials and nonmagnetic materials. The magnetisable particles may comprise a coating of silica or polymer cores with magnetic shells. The nonmagnetic core particles may comprise silica or other polymers.

In some embodiments, the magnetisable particles may contain alternating magnetic direction layer separated by an insulating layer.

The magnetisable particles may comprise a dielectric silica core coated with a magnetic shell. The magnetic shell may be formed from Co, FePt, or Fe₃O₄. The shell may also comprise a stabiliser such as silica shell or polyelectrolyte layer. The magnetisable particles may be mesoporous magnetisable particles.

The coating on the magnetisable particle may define the interactions between the magnetisable particles and biological molecules (such as analytes) and their biocompatibility. The coating can be used to define the surface charge, which together with the coating may alter the hydrodynamic size of the magnetic particle. The hydrodynamic size of the magnetisable particle may alter the functionality of the magnetic particle.

The magnetisable particles may be coated with specific coatings that provide forces of electrostatic and steric repulsion. Such coatings may assist stabilisation of the magnetisable particles which may prevent agglomeration or precipitation of the magnetisable particles.

The magnetisable particles may comprise of a coating formed from inorganic materials. Such magnetisable particles may be formed with a core-shell structure. For example, a magnetisable particle coated by biocompatible silica or gold (e.g. alloy magnetic nanoparticles, FeCo and CoPt coated with silica). The shell may provide a platform to modify the magnetisable particles with ligands (e.g. thiols). Other inorganic coating materials may include titanate or silver. For example, silver-coated iron oxide magnetisable particles may be synthesised and integrated with carbon paste.

The shell may be formed from silica. A benefit of coating with silica is the ability of the silica-coated magnetisable particles to bind covalently with versatile functional molecules and surface-reactive groups. The silica shell may be manufactured, for example, by the Stober method using sol-gel principles or the Philipse method or a combination thereof. The core of the magnetisable particle may be coated with tetraethoxysilane (TEOS), for example, by hydrolysis of TEOS under basic conditions which condenses and polymerises TEOS into a silica shell on the surface of the magnetic core. A cobalt magnetisable particle may be coated using a modified Stober method that combines 3-aminopropyl) trimethoxysilane and TEOS.

The Philipse method forms a silica shell of sodium silicate on the magnetic core. A second layer of silica may be deposited by the Stober method. The reverse microemulsion method may be used to coat with silica. This method may be used with surfactants. The surfactant may be selected from Igeoal CO-520 to provide a silica shell thicknesses of about 5 to about 20 nm. Preferably the reagents for manufacturing silica shells is selected from amino-terminated silanes or alkene-terminated silanes. Preferably the amino-terminated silanes is (3-aminopropyl) trimethoxysilane (APTMS). Preferably the alkene-terminated silanes is 3-methacryloxypropyl) trimethoxylsilane.

The magnetisable particles may be coated with gold. Gold-coated iron oxide nanoparticles may be synthesised by any one of chemical methods and reversed microemulsion. Gold-coated magnetisable particles may be synthesised by directly coating gold on the magnetisable particle core. Alternately, the gold-coated magnetisable particle may be synthesised by using silica as an intermediate layer for the gold coating. Preferably reduction is used method to deposit gold shells on the magnetisable particles.

Metal oxide or silica-coated magnetic cores may first be functionalized with 3-aminopropyl) trimethoxysilane prior to the electrostatically attachment of about 2 to about 3 nm gold nanocrystal seeds (from chloroauric acid) to the surface followed by the addition of a reducing agent to form the gold shell. Preferably the reducing agent is a mild reducing agent selected from sodium citrate or tetrakis(hydroxymethyl)phosphonium chloride. In some embodiments the gold shell is formed from reduction of gold (III) acetate (Au(OOCCH₃)₃). In some embodiments the gold shells are formed on metallic magnetic cores (e.g. nickel and iron) by reverse micelles.

The magnetisable particles may be functionalised with organic ligands. This may be performed in-situ (i.e. functional ligands provided on the magnetisable particle during the synthesis step), or post-synthesis. The magnetisable particles may be functionalised with terminal hydroxyl groups (—OH), amino groups (—NH₂), and carboxyl groups (—COOH). This may be achieved by varying the surfactant (e.g., dextran, chitosan, or poly(acrylic acid)) used in the hydrothermal synthesis.

The functionalisation of the magnetisable particle post-synthesis may allow for the functionalisation of customised ligands on any magnetisable particle surface. Post-synthesis functionalisation may be carried out by ligand addition and ligand exchange. Ligand addition comprises the adsorption of amphiphilic molecules (that contain both a hydrophobic segment and a hydrophilic component) to form a double-layer structure. Ligand-exchange replaces the original surfactants (or ligands) with new functional ligands. Preferably the new ligands contain a functional group that is capable of binding on the magnetisable particle surface via either strong chemical bonding or electrostatic attraction. In some embodiments the magnetisable particle also includes a functional groups for stabilisation in water and/or bio-functionalisation.

The magnetisable particles may be coated with ligands that enhance ionic stability. The functional groups may be selected from carboxylates, phosphates, and catechol (e.g. dopamine). The ligand may be a siloxane group for coating of surfaces enriched in hydroxyl groups (e.g. metal oxide magnetic particle or silica-coated magnetic particles). The ligand may be a small silane ligand that links the magnetisable particle and various functional ligands (e.g. amines, carboxylates, thiols, and epoxides. The silane ligand may be selected from N-(trimethoxysilylpropyl)ethylene diaminetriacetic acid and (triethoxysilylpro-pyl) succinic anhydride to provide a carboxylate-terminated magnetic particles. The functional groups may be selected from phosphonic acid and catechol (to provide hydrophilic tail groups). The functional groups may be selected from amino-terminated phosphonic acids. Functional groups may be selected from 3-(trihydroxysilyl) propyl methylphosphonate for dispersion in aqueous solution. The ligand may be selected from dihydroxyhydrocinnamic acid, citric acid, or thiomalic acid for magnetisable particles for dispersion in water.

In some embodiments the magnetisable particle is functionalised with polymeric Ligands. The polymer may be selected from natural polymers (e.g. starch, dextran or chitosan), PEG, polyacrylic acid (PAA), poly(methacrylic acid) (PMAA), poly(N,N-methylene-bisacrylamide) (PMBBAm), and poly(N,N/-methylenebisacrylamide-co-glycidyl methacrylate) (PMG).

The functional group on the magnetisable particle surface serves as a linker to bind with a complementary biomolecules. The biomolecules may be a small biomolecules. The small biomolecule may be selected from vitamins, peptides, and aptamers. The biomolecule may be a larger biomolecule. The larger biomolecule may be selected from DNA, RNA and proteins.

In relation to nucleic acid attachment, the nucleic acid may be conjugated by non-chemical methods (e.g. electrostatic interaction) or chemical methods (e.g. covalent bonding). The nucleic acid chain may be modified with functional groups. The functional groups may be selected from thiols or amines, or any combination thereof.

The conjugation of larger biomolecules may rely on their specific binding interaction with a wide range of subtracts and synthetic analogues, such as specific receptor-substrate recognition (i.e. antigen-antibody and biotin-avidin interactions).

A specific pair of proteins may be used to immobilise species on the magnetic particle. Physical interactions include electrostatic, hydrophilic-hydrophobic, and affinity interactions.

In some embodiments the biomolecule has a charge opposite to that of the magnetic polymer coating (e.g. polyethylenimine or polyethylenimine). For example, a positively charged magnetisable particle binding with negatively charged DNA.

The magnetisable particle may utilise the biotin-avidin interaction. The biotin molecules and tetrameric streptavidin have site-specific attraction with low nonspecific binding for controlling the direction of interacted biomolecules, such as the exposure of the Fab region of an antibody toward its antigen.

The magnetisable particle may bind to biomolecules using covalent conjugation. The covalent conjugation may be selected from homobifunctional/heterobifunctional cross-linkers (amino group), carbodiimide coupling (carboxyl group), maleimide coupling (amino group), direct reaction (epoxide group), maleimide coupling (thiol group), schiff-base condensation (aldehyde group), and click reaction (alkyne/azide group).

The magnetisable particles may have an average particle size of about 5, 10, 50, 100, 150, 200, 250, 300, 350, 400, 450 or 500 nm, and suitable ranges may be selected from between any of these values, (for example, about 5 to about 500, about 5 to about 400, about 5 to about 250, about 5 to about 100, about 5 to about 50, about 10 to about 500, about 10 to about 450, about 10 to about 300, about 10 to about 150, about 10 to about 50, about 50 to about 500, about 50 to about 350, about 50 to about 250, about 50 to about 150, about 100 to about 500, about 100 to about 300, about 150 to about 500, about 150 to about 450 or about 200 to about 500 nm).

The magnetisable particles may have an average particle size of about 500, 550, 600, 650, 700, 750, 800, 850, 900, 950 or 1000 nm, and suitable ranges may be selected from between any of these values, (for example, about 500 to about 1000, about 500 to about 850, about 500 to about 700, about 550 to about 1000, about 550 to about 800, about 600 to about 1000, about 600 to about 900, about 650 to about 1000, about 650 to about 950, about 650 to about 800 or to about 700 to about 1000 nm).

The magnetisable particles may have an average particle size of about 1000, 1500, 2000, 2500, 3000, 3500, 4000, 4500 or 5000 nm, and suitable ranges may be selected from between any of these values, (for example, about 1000 to about 5000, about 1000 to about 4000, about 1500 to about 5000, about 1500 to about 4500, about 1500 to about 3500, about 2000 to about 5000, about 2000 to about 4000, about 2500 to about 5000, about 2500 to about 3500, about 3000 to about 5000 nm).

The variation in the particle size of the magnetisable beads may be less than 25, 15, 10, 9, 8, 7, 6, 5, 4, 3, 2 or 1%, and suitable ranges may be selected from between any of these values.

Described is a method for detecting analytes in a sample comprising:
bringing a sample comprising a target analyte into contact with particles, the particles being coated with binding molecules complementary to the target analyte resulting in bound and unbound binder complexes,
positioning the particles, comprising both bound and unbound binder complexes, in proximity to a magnetic or electric field sensor,
changing the magnetic or electric field sufficient to release at least a portion of the particles, comprising both bound and unbound binder complexes, from their proximity to the magnetic or electric field sensor, and
measuring changes in a magnetic or electrical signal detected from the net movement (i.e. translational or rotational movement) of particles relative to the magnetic or electric sensor respectively.

As shown in FIG. 1, a set up according to an embodiment of this method may broadly comprise a microfluidic device or a sample well, a sensor, a magnet, a signal amplifier, an analog to digital converter and a computer.

The target analyte can be any substance or molecule that is complementary to and capable of being bound by a binding molecules provided to the magnetisable particles. For example, the target analyte can be selected from the group comprising of a protein, a peptide, a nucleic acid, lipid or a carbohydrate, biochemical, biological agent, virus, bacteria, etc.

The target analyte may be a protein or a fragment thereof selected from the group comprising of an antibody, an enzyme, a signalling molecule or a hormone.

The target analyte may be a nucleic acid selected from the group comprising of DNA, RNA, cDNA, mRNA, or rRNA.

The method may detect more than one target analyte in a single sample. For example, the method may detect two or more, three or more, four or more, five or more, 10 or more, 15 or more, 20 or more 40 or more or 50 or more target analytes in a single sample.

The sample to be analysed can be any sample that may contain one or more target analyte(s). For example, the sample may be a clinical, veterinary, environmental, food, forensic or other suitable biological samples.

The clinical sample may be selected from a bodily fluid. For example, the bodily fluid may be selected from blood, sweat, saliva, urine, sputum, semen, mucous, tears, cerebral spinal fluid, amniotic, gastric juices, gingival crevicular or interstitial fluids.

The environmental sample may be selected from the group comprising of water, soil or an aerosol.

A benefit of the present invention may be that the sample preparations are not laborious or difficult to prepare. The sample preparation utilises established biochemistries for molecular functionalisation and attachment, either on microfluidic surfaces or magnetisable particle surfaces.

The sample to be analysed may be added directly to a sample well or microfluidic device without additional processing.

The sample may be subjected to one or more sample processing steps. It will be understood that suitable sample processing steps may depend on the type and/or nature of the sample to be analysed. In some embodiments, sample processing steps may be selected from the group comprising dilution, filtration, or extraction (e.g. liquid-liquid, solid-phase). This may also be achieved through microfludic featured and designs or the use of centripetal force. For example, whole blood samples may be filtered using cellulose based or other filters to isolate plasma to be analysed.

A first step of the method may comprise combining the sample to be analysed with a preparation containing freely diffusible magnetisable particles that are coated with binding molecules (the binder complex) complementary to the target analyte in a sample well or sample reservoir. Where appropriate, the term ‘binder complex’ may be used interchangeably to refer to the magnetisable particles that are coated with binding molecules.

In some embodiments the magnetisable particles may have limited diffusibility. This may occur where the magnetisable particles are cross-linked or derivatised with macromolecules. The macromolecules may be a hydrogel or PEG linker. This may occur when using the device for multiplexing assays for detection of multiple targets or samples in the one sample.

The present method may improve the rate at which the binding molecules bind target analytes by providing binder complexes that are mobile and freely diffusible in solution. When the sample and binder complex preparation are combined, the binder complexes are freely diffusible and the binding molecules are able to interact with the target analytes throughout the entire sample volume. As both the binder complex and target analytes are freely diffusible and suspended in the sample volume, the average physical distance between a target analyte and a binder complex is likely to be small. As such, the rate of binding may be improved and binding equilibrium may be achieved significantly faster.

In detection assays such as ELISA, binding molecules such as antibodies are immobilised on macro scale objects such as the surface of a test well. In such a method, the physical distance between a target analyte and an antibody may vary significantly depending on the position of the analyte in the sample volume. For example, a target analyte near the top of the sample volume may be quite far from the immobilised antibody and will be less likely to be captured and bound. As such, the rate of binding may be limited by the rate at which target analytes diffuses in the sample volume towards the immobilised antibodies.

The sample and binder complex may be allowed to combine for a suitable amount of time to enable binding molecules to reach binding equilibrium. In some embodiments, the suitable amount of time to enable binding to reach equilibrium may be about one, two, three, four, five, 10, 20, 30, 45, 60, 90, 120, 180, 240, 300 or 360 second(s) and useful ranges may be selected between any of these values, (for example from about 1 to 30, 1 to 60, 1 to 120, 10 to 30, 10 to 60, 10 to 90, 30 to 60, 30 to 90, 30 to 120, 60 to 90, 60 to 120, 60 to 180, 90 to 120, 90 to 180, 90 to 240, 180 to 240, 180 to 300, 180 to 360 seconds).

The magnetic field generator may be used to induce magneto-hydrodynamic mixing of the sample to improve the rate at which binding equilibrium is reached. In such an embodiment, the magnetic field generator is used to induce movement of the binder complexes in the sample volume.

A signal to allow quantification of the analyte in the sample is generated by measuring the net change in magnetic field as the bound and unbound analyte complexes move relative to the magnetic field sensor.

A further step of the present method may comprise applying a magnetic field to the sample to position binder complexes in proximity to the magnetic field sensor. A magnetic field generator as described in paragraph may be used to generate a magnetic field to manipulate bound and unbound binder complexes into a position that enables the magnetic field sensor to effectively measure the changes in magnetic field generated by the magnetisable particles.

In some embodiments, the binder complexes may be positioned in proximity to the magnetic field sensor using microfluidics, electrophoresis, optical tweezers, acoustics, piezoelectrics, pump and/or suction, passive capillary pumps or other suitable means. In other embodiments, the binder complexes may be positioned by centrifugation.

In some embodiments, the magnetic field may be generated in a direction that moves the magnetisable particles in the sample volume towards the magnetic field sensor. The magnetic field sensor may be provided in any position relative to the test well or microfludic device. For example, if the magnetic field sensor is positioned below a test well or sample reservoir, the magnetic field will move the magnetisable particles towards the bottom of the test well or sample reservoir. In another example, if the magnetic field sensor is positioned above a test well or sample reservoir, the magnetic field will move the magnetisable particles towards the top of the test well or sample reservoir.

In case of centrifugation, the sensor may be oriented on a vertical axis with its sensing axis pointing horizontally inward or outward.

The magnetic field generated may be static or dynamic.

The strength of the magnetic field generated may be modulated.

Without wishing to be bound by theory, the modulation of this magnetic field (i.e. the bias field) has the primary function of aligning the magnetisable particles to the sensor to achieve the highest sensitivity of detection during detection. For ferromagnetic particles, given they have their own permanent magnetic field, where the bias field is switched off resulting in misalignment of the magnetic particles. For paramagnetic (or superparamagnetic) particles, as their magnetic field has to be induced by an external field, the bias field serves the additional function of inducing such a field.

The bias field may be modulated in order to support different magnetisable particles since different particles (whether by chemical composition or physical size) may require different bias field strengths and configurations.

The magnetic field may be generated and positioned in such a way as to maximise its effect on the magnetisable particles but minimise its effect on the magnetic field sensor. The magnetic field generator may be generated and/or positioned in close proximity to the magnetic field sensor. In some embodiments, the magnetic field generator is positioned above, below or beside the magnetic field sensor. In some embodiments, the magnetic field generator may be positioned on the same plane vertical or horizontal plane as the magnetic field sensor.

The magnetic field generator may not be activated or the magnetic field may not be present altogether.

A further step of the method may comprise changing the magnetic field sufficiently to release at least a portion of the binder complexes from their proximity to the magnetic field sensor when the bound and unbound binder complexes are positioned in proximity to the magnetic field sensor.

The magnetic field may be reduced gradually.

The magnetic field may be removed instantly.

The magnetic field may be variable in shape.

As the magnetic field applied to the sample is reduced and/or removed, the bound and unbound binder complexes are released from the magnetic field and may freely diffuse away (translational movement) from their proximity to the magnetic field sensor. The binder complex may also rotate relative to the magnetic field sensor (rotational movement) as the magnetic field applied to the sample is reduced and/or removed.

According to the present method, bound and unbound binder complexes may be distinguished based on the change in molecular diffusion characteristics according to Graham's law of molecular diffusion which states that the rate of diffusion is inversely proportional to the square root of its molecular weight. The rate of diffusion may be calculated using the formula below:

$$\frac{{R}_{A}}{{R}_{B}} = \sqrt{\frac{{M}_{B}}{{M}_{A}}}$$

where
R_{A}=the rate of diffusion for molecule A,
R_{B}=the rate of diffusion for molecule B,
M_{A}=the molecular weight of molecule A, and
M_{B}=the molecular weight of molecule B.

As a binder complex that is bound to a target analyte will have larger molecular weight compared to an unbound binder complex, the unbound binder complex will have a higher rate of diffusion according to Graham's law. Therefore, bound and unbound binder complexes may be distinguished based on their kinetic profiles.

A further step of the present method may comprise measuring the changes in a magnetic signal detected from the magnetisable particles as they move (via translational and/or rotational movement) in relation to the magnetic field sensor. The magnetic field sensor, as described in detail the preceding paragraphs, measures the changes in the magnetic field strength generated by the magnetisable particles over time. The present method uses magnetic field changes over time which only requires one binding molecule for binding of the target analytes.

In some embodiments, magnetic field changes over time may be determined by measuring magnetoresistance effect and the signal drop-off over time.

The magnetic field signal generated by the magnetisable particles in relation to the magnetic field sensor conforms to the magnetic dipole field equation:

$$B ( m , r ) = \frac{{μ}_{0}}{4 π} \frac{3 ( m \cdot \hat{r} ) \hat{r} - m}{{r}^{3}}$$

where
   B is the field
   r is the vector from the position of the dipole to the position where the field is being measured
   r is the absolute value of r: the distance from the dipole
   \hat{r}=r/r is the unit vector parallel to r;
   m is the (vector) dipole moment
   μ₀ is the permeability of free space

Based on the magnetic dipole field equation, the detection signal drops off to the distance cubed from the magnetic field sensor. This phenomenon in conjunction with the diffusion kinetics described above can be used for signal generation described in the proceeding paragraphs.

Due to the higher diffusion rate of unbound binder complexes, the unbound binder complexes may move further away from the sensor at a faster rate when compared to binder complexes that are bound to target analytes. The difference in diffusion rate will generate a magnetic field decay signal over time. The rate of decay is dependent on the molecular weight of the bound and unbound binder complexes where an unbound binder complex will have a faster rate of decay compared to a bound binder complex.

The rate of decay may be modelled in a decay curve. The decay curve may be used to distinguish between bound and unbound binder complexes. For example, an accelerated decay curve may indicate unbound binder complexes and an attenuated decay curve may indicate bound binder complexes.

The method may comprise multiple rounds of the following steps to generate a signal curve over time to distinguish bound and unbound binder complexes to quantify the target analyte.
Applying a magnetic field to position the magnetisable particles in proximity to a magnetic field sensor.
Changing the magnetic field sufficient to release at least a portion of the magnetisable particles from their proximity to the magnetic field sensor.
Measuring changes in a magnetic signal detected from the magnetisable particles as the magnetisable particles move away from the magnetic sensor.

The method may comprise a reference calibration step by measuring the total magnetic field strength generated by the bound or unbound binder complexes.

The magnetic field signal generated by the magnetisable particles may be due to the inherent properties of the magnetisable particles or it may be induced by an external magnetic field.

The magnetic field sensor is positioned in such a way as to maximise its sensing of the magnetisable particles but minimise sensing of the magnetic field generator.

The magnetic field or signal from the magnetisable particles can be inherent to its atomic construct, or can be induced by an external magnetic field.

Data acquisition by the sensor may be synchronised with the microfluidic device. This may allow data from the detected sensor to be characterised between sample data or environmental or ambient data. For example, detection by the magnetic sensor of a signal absent sample injection into the microfluidic device would characterise that data as environmental or ambient data. Characterisation of the data as environmental or ambient data may assist to establish background and may also assist preparing calibration data.

Where the magnetic sensor detects a signal following injection of the sample into a microfluidic device, which coincides with the positioning of the magnetisable particles into close proximity with the magnetic sensor, such data can be characterised as sample data.

System utilization of such sensing can deliver embodiments in which microfluidic quality control measurement can take place confirming sample displacement and sensing times.

Data acquisition from the sensor may be continuous. That is, the magnetic sensor continuously transmit signals and, based on the synchronisation of the data collection with the injection of sample into the microfluidics device, characterises the data as sample data or background data.

The sensor data may be acquired over a period of time in order to measure changes in the magnetic signal from the magnetisable particles. Actions or events may be inferred from changes in the sensed magnetic signal. The actions or events include may include movement of the magnetisable particles from fluid flow, from external magnetic forces, or from diffusion.

The method may comprise processing the raw data output from the magnetic field sensor to quantify the amount of target analyte in the sample. Raw data processing may be carried out using a combination of hardware and software implementations described in detail in the preceding paragraphs.

An evaluation of the analytical performance of a detection methodology is often done by measuring dose-response curves from which the limit of detection (LoD) can be derived. The LoD is the lowest quantity of a substance such as a biomarker that can be detected for a chosen confidence level. The chosen assay (biomarker, biomaterials, sample matrix, incubation times, etc.) may have a strong influence on the LoD. Also used is the limit of quantification (LoQ) that is the lowest biomarker concentration that can be quantified with a given required precision. The LoQ is close to the LoD if a dose-response curve has a good sensitivity, i.e. if the signal changes strongly as a function of the target concentration.

The present method may provide for an LoQ of about 0.05, 0.1, 0.2, 0.3, 0.4, 0.5, 0.6, 0.7, 0.8, 0.9, 1.0, 1.5 or 2.0 pg/mL, and suitable ranges may be selected from between any of these values.

The present method may provide for an LoD of about 0.1, 1.1, 1.2, 1.3, 1.4, 1.5, 1.6, 1.7, 1.8, 1.9 or 2.0 pg/mL, and suitable ranges may be selected from between any of these values.

The invention describes methods, reagents and systems that detect and quantitate analytes in a sample.

It will be appreciated that the present method may broadly be used in any application requiring detection and/or quantification of a target analyte. In particular, the method may be used in applications requiring
rapid determination, or
sensitive determination, or
quantitative determination, or
or any combination of (i) to (iii);
of the presence of target analytes in samples.

For example, suitable applications may include clinical, veterinary, environmental, food safety or forensic applications.

In some embodiments, the clinical application may include diagnostic detection of biomarkers in a sample that may be indicative of a clinical condition. In one example, the method may be used for rapid, sensitive, and quantitative diagnostic detection of specific antibodies in a blood sample which may indicate potential infection by a pathogen. In a further example, the method may be used for diagnostic detection of specific protein biomarkers that are overexpressed in cancers. The diagnostic detection may be performed on samples across different species.

The clinical condition may be selected from infections, such as infections from bacteria, fungi, viruses (e.g. hepatitis, SARS-CoV-19 and HIV) (e.g. biomarkers such as hepatitis, SARS-CoV-19 and HIV antibodies), parasites (e.g. microbial parasites [e.g. malarial], nematodes, insect parasite).

The clinical condition may be selected from diseases such as cardiac disease (biomarkers such as BNP), cancer (e.g. solid organ cancers, blood cancers, other cancers), (e.g. biomarkers such as Ca-125 and other tumour markers), neurological diseases (e.g. multiple sclerosis, Alzheimer's disease, Parkinson's disease, Huntington's disease) (e.g. biomarkers such as CNS immunoglobulins), respiratory diseases (e.g. biomarkers such as serum ACE), liver disease (e.g. biomarkers such as liver function tests and albumin), kidney disease (e.g. biomarkers such as creatinine and protein).

The clinical condition may be selected from organ injury or failure such as brain injury (e.g. biomarkers such as Glial fibrillary acidic protein or GFAP), kidney injury (e.g. biomarkers such as serum creatine), heart damage (e.g. biomarker such as creatine kinase-muscle), lung damage (e.g. biomarkers such as intercellular adhesion molecule-1 or ICAM1), or liver injury (e.g. biomarker such as alkaline phosphatase).

The clinical condition may be selected from endocrine disorders such as diabetes (e.g. biomarkers such as insulin, elevated, HbA1C, thyroid dysfunction, thyroid hormone, pituitary disorders (e.g. biomarkers such as ACTH, prolactin, gonadotrophins, thyroid stimulating hormone, growth hormone, antidiuretic hormone), parathyroid disorders (e.g. biomarkers such as, parathyroid hormone), adrenal disorder (e.g. biomarkers such as cortisol, aldosterone, adrenaline, DHEAS), sex hormone imbalance (e.g. biomarkers such as androgens and estrogens), carcinoid tumour (e.g. biomarkers such as 5-HIAA, VIPoma, serum VIP), elevated bone turnover (e.g. biomarkers such as P1NP).

The clinical condition may be selected from lipid disorders (e.g. biomarkers such as cholesterols and triglycerides)

The clinical condition may be selected from nutritional disorders (e.g. vitamin deficiencies, malabsorption syndrome, malnutrition, disorders of vitamin metabolism), (e.g. biomarkers such as vitamin levels, iron levels, mineral levels).

The clinical condition may be selected from inflammation or inflammatory disorders (e.g. biomarkers such as ESR, CRP and other acute phase proteins).

The clinical condition may be selected from autoimmune diseases (e.g. biomarkers such as specific antibody markers).

The clinical condition may be selected from allergic disease (e.g. biomarkers such as tryptase).

The clinical condition may be selected from physical trauma such as electrocution (e.g. biomarkers such as creatinine kinase).

The clinical condition may be selected from immune deficiency disorders (e.g. common variable immune deficiency), (e.g. biomarkers such as complement, leucocytes and immunoglobulins).

The clinical condition may be selected from clotting disorders (e.g. thrombophilia) (e.g. biomarkers such as biomarkers such as clotting factors and other markers).

The clinical condition may be selected from inherited or acquired enzyme disorders, deficiency or excess and other congenital or acquired defects of metabolism (e.g. Bartter syndrome, congenital adrenal hyperplasia), (e.g. biomarkers such as electrolytes, enzyme levels, metabolic products of enzymes).

The clinical condition may be selected from electrolyte disturbance such as hyperkalaemia and hypernatraemia (e.g. biomarkers such as electrolytes).

The clinical condition may be selected from drug adverse effects or poisoning (eg. biomarkers such as drug levels and levels of drug metabolites.

The clinical condition may be selected from adverse effects or poisoning from exposure to chemical to biological weapons or other environmental chemical and biological agents.

Specific to veterinary medicine, the clinical condition may be selected from renal failure, FIV/AIDS (Feline), cancers, and any biomarker for organ function/failure.

In some embodiments, the clinical conditions may be conditions in veterinary subjects such as feline, canine, bovine, ovine, equine, porcine, or murine.

In some embodiments, the environmental application may include detection of pollutants in an environmental sample. The environmental pollutant may be selected from such pollutants as, for example, lead, particulate matter, micro plastic and hormones.

For example, the method may be used for monitoring and quantifying heavy metals in a water sample.

In some embodiments, the food safety application may include detection of pathogen in food samples. For example, the method may be used to rapidly and sensitively detect post-pasteurisation contamination in milk by bacterial pathogens.

### EXAMPLES

The purpose of this study was to test the sensitivity and range of detection of the apparatus using ferromagnetic particles. Ferromagnetic particles generate their own magnetic field without needing to be magnetised by an external magnetic field.

Main components of the apparatus and sensor data parameters are summarised below.
Magnetic sensor: Honeywell HMC 2003 magnetometer.
Amplifier: Honeywell HMC2003 in-built amplifier
Electromagnet:
   5V DC with 10N force
Acquisition of sensor data:
   Approximately 0.007 seconds per read
   2,500 reads per sample
   approximately 17.5 seconds total read time

The apparatus is configured with the electromagnet located upper-most, the microfluidic chip positioned in the middle placed over the magnetic sensor located bottom-most.

The magnetisable particles used are Spherotech SVFM-20-5 (2.0-2.9 micrometer) Streptavidin coated ferromagnetic particles. The magnetisable particles are functionalised with biotinylated “detection” anti-Human Albumin antibody from DY1455 ELISA kit.

The experimental protocol is summarised below.
Concentrations of Human Albumin recombinant protein tested (DY1455 ELISA kit):
   Sample 1-0 pg/ml (control)
   Sample 2-0.1 pg/mL
   Sample 3-1 pg/mL
   Sample 4-10 pg/mL
   Sample 5-100 pg/mL
   Sample 6-1,000 pg/ml
For each protein concentration tested:
   5 microlitres of magnetisable particles (Spherotech Ferromagnetic Beads 1% w/v)
   2 nanogram of anti-Albumin Antibody (Biotinylated “Detection” antibody from DY1455 ELISA kit)
All components mixed and sensed in a test volume of 50 microlitres

After being introduced into the microfluidics chip, the magnetisable particles were positioned over the sensor using an electromagnet. The electromagnet was activated to bring the magnetisable particles into close proximity to the magnetic sensor. The electromagnet was controlled to collapse the biasing magnetic field and the magnetic field sensor measured changes in the magnetic field strength generated by the magnetisable particles over time as they diffused away from the magnetic sensor. The apparatus determines the amount of analyte in the sample by measuring the net movement of the magnetisable particles relative to the magnetic field sensor.

The magnetic sensor data was acquired for each concentration of Human Albumin.

Shown in Table 1 is the average sensor reading across 2,500 sample reads expressed in volts (v) for each concentration of the Human Albumin samples tested below.

TABLE 1
concentration of Human Albumin vs average sensor reading

| Human Albumin protein | Sensor Value |
|---|---|
| concentration (pg/ml) | (volts - v) |
| 0 | 2.536 |
| 0.1 | 2.549 |
| 1 | 2.645 |
| 10 | 2.676 |
| 100 | 2.702 |
| 1,000 | 2.741 |

R2 value - 0.9171

The results demonstrate sensitivity and range of the apparatus for detecting an analyte (Human Albumin) using functionalised ferromagnetic particles across at least 5-orders of magnitude from 0.1 to 1,000 pg/mL.

The purpose of this test is to demonstrate optimisation of the upper dynamic range of the detection of Human Albumin in Example 1 by using an increased amount of detection antibody.

The same apparatus as described in Example 1 is used for Example 1a.

The experimental protocol is varied by using 20 nanograms of anti-Albumin Antibody instead of 2 nanograms in Example 1. A higher concentration of 10,000 pg/mL was also tested.

Shown in Table 2 is the average sensor reading across 2,500 sample reads expressed in volts (v) for each concentration of the Human Albumin tested.

TABLE 2
concentration of Human Albumin vs average sensor reading

| Human Albumin protein | Sensor Value |
|---|---|
| concentration (pg/ml) | (volts - v) |
| 0 | 2.700 |
| 1 | 2.769 |
| 10 | 2.773 |
| 100 | 2.805 |
| 1,000 | 2.849 |
| 10,000 | 2.863 |

R2 value - 0.9483

The purpose of this test is to demonstrate the flexibility of the apparatus and method for detecting analytes in an inverted physical orientation.

The experimental protocol used is as described in Example 1 except the highest concentration of Human Albumin tested is 100 pg/mL.

The components of the apparatus used in this test is as described in Example 1 except the apparatus is configured with the magnetic sensor upper-most, the microfluidic chip is inverted (upside down orientation) and positioned below the magnetic sensor with the electromagnet located bottom-most.

Shown in Table 3 is the average sensor reading across 2,500 sample reads expressed in volts (v) for each concentration of the Human Albumin samples tested below.

TABLE 3
concentration of Human Albumin vs average sensor reading

| Human Albumin protein | Sensor Value |
|---|---|
| concentration (pg/ml) | (volts - v) |
| 0 | 3.710 |
| 0.1 | 3.713 |
| 1 | 3.737 |
| 10 | 3.746 |
| 100 | 3.748 |

R2 value - 0.8817

The purpose of this test is to demonstrate detection of an analyte using a device employing suction and microfluidic features to position the particles in proximity to the sensors without the use of an electromagnet.

Main components of the apparatus and sensor data parameters are summarised below.
Magnetic sensor: Honeywell HMC 2003 magnetometer
Amplifier: Honeywell HMC2003 in-built amplifier
Acquisition of sensor data:
   Approximately 0.004 seconds per read
   5,000 reads per sample
   approximately 20 seconds total read time

The magnetisable particles used are Spherotech SVFM-20-5 (2.0-2.9 micrometer) Streptavidin coated ferromagnetic particles. The magnetisable particles are functionalised with biotinylated “detection” anti-Human Albumin antibody from DY1455 ELISA kit.

The microfluidic chip is configured with a 1.5% low-melt agarose trap. A pump is used to generate a light suction-induced flow of the particles in microfluidic channels. Magnetisable particles in the suction-induced flow are trapped by the agarose trap whilst allowing sample fluid to flow through the agarose trap, bringing the particles into close proximity to the magnetic sensor. Suction was set to 2 microlitres per second and actuating for 1 second followed by 4 seconds of no suction (passive flow) every 5 seconds.

The experimental protocol is summarised below.
Concentrations of Human Albumin recombinant protein tested (DY1455 ELISA kit):
   Sample 1-0 pg/ml (control)
   Sample 2-0.1 pg/ml
   Sample 3-1 pg/ml
   Sample 4-10 pg/mL
   Sample 5-100 pg/ml
   Sample 6-1,000 pg/mL
   Sample 7-10,000 pg/ml
For each protein concentration sample tested:
   5 microlitres of magnetisable particles (Spherotech Ferromagnetic Beads 1% w/v)
   2 nanogram of anti-Albumin Antibody (Biotinylated “Detection” antibody from DY1455 ELISA kit)
All components mixed and sensed in a test volume of 50 microlitres.

When samples are introduced to the microfluidic chip, the pump is actuated for 3 cycles (i.e. 3 cycles of 1 second of active flow followed by 4 seconds of passive flow). At the end of the third cycle of pump actuation, the magnetic sensor acquires data for approximately 20 seconds.

Shown in Table 4 is the average sensor reading across 1,250 sample reads (for approximately 5 seconds) expressed in volts (v) for each concentration of the Human Albumin tested.

TABLE 4
concentration of Human Albumin vs average sensor reading

| Human Albumin protein | Sensor Value |
|---|---|
| concentration (pg/ml) | (volts - v) |
| 0 | 2.201 |
| 0.1 | 2.230 |
| 1 | 2.230 |
| 10 | 2.267 |
| 100 | 2.263 |
| 1,000 | 2.271 |
| 10,000 | 2.274 |

R2 value - 0.9219

The purpose of this test is to demonstrate detection of an analyte using a apparatus employing centrifugation to position the particles in proximity to the sensors.

Main components of the apparatus and sensor data parameters are summarised below.
Magnetic sensor: Honeywell HMC 2003 magnetometer
Amplifier: Honeywell HMC2003 in-built amplifier
Acquisition of sensor data:
   ^{˜}0.004 seconds per read
   8,750 reads per sample
   approximately 35 seconds total read time

The magnetisable particles used are Spherotech SVFM-20-5 (2.0-2.9 micrometer) Streptavidin coated ferromagnetic particles. The magnetisable particles are functionalised with biotinylated “detection” anti-Human Albumin antibody from DY1455 ELISA kit.

The experimental protocol is summarised below.
Concentrations of Human Albumin recombinant protein tested (DY1455 ELISA kit):
   Sample 1-0 pg/ml (control)
   Sample 2-0.1 pg/ml
   Sample 3-1 pg/mL
   Sample 4-10 pg/ml
   Sample 5-100 pg/mL
   Sample 6-1,000 pg/ml
   Sample 7-10,000 pg/mL
For each protein concentration tested:
   20 microlitres of magnetisable particles (Spherotech, 2 μm Ferromagnetic Beads 1% w/v)
   8 nanogram of anti-Albumin Antibody (Biotinylated “Detection” antibody from DY1455 ELISA kit).
All components mixed and sensed in a test volume of 200 microlitres

A sample receptacle comprising a circular channel having a radius of 42 mm was used to receive the sample.

The sample receptacle containing the sample is centrifuged for 4 minutes and 15 seconds at 520 rpm and decelerated to a stop over approximately 10 seconds. The sample receptable is maintained in a stationary position after the sample receptacle is decelerated to a stop. The magnetic sensor was positioned to be in close proximity of the circular channel (at the outside circumference).

Shown in Table 5 is the average sensor reading across 2,500 sample reads (for approximately 10 seconds) expressed in volts (v) for each concentration of the Human Albumin samples tested. The sensor values in Table 5 are set to reflect a negative ladder of results with the higher concentration recording a lower value.

TABLE 5
concentration of Human Albumin vs average sensor reading

| Human Albumin protein | Sensor Value |
|---|---|
| concentration (pg/ml) | (volts - v) |
| 0 | 1.578 |
| 0.1 | 1.595 |
| 1 | 1.309 |
| 10 | 1.447 |
| 100 | 1.197 |
| 1,000 | 0.959 |
| 10,000 | 0.719 |

R2 value - 0.9395

The purpose of this test is to demonstrate detection of an analyte using a apparatus employing a passive biasing system to position the particles in proximity to the sensors without the use of magnets or electromagnets.

Main components of the apparatus and sensor data parameters are summarised below.
Magnetic sensor: Honeywell HMC 2003 magnetometer
Amplifier: Honeywell HMC2003 in-built amplifier
Acquisition of sensor data:
   Approximately 0.004 seconds per read
   2,500 reads per sample
   approximately 10 seconds total read time

The magnetisable particles used are Spherotech SVFM-20-5 (2.0-2.9 micrometer) Streptavidin coated ferromagnetic particles. The magnetisable particles are functionalised with biotinylated “detection” anti-Human Albumin antibody from DY1455 ELISA kit.

The experimental protocol is summarised below.
Concentrations of Human Albumin recombinant protein tested (DY1455 ELISA kit):
   Sample 1-0 pg/ml (control)
   Sample 2-1 pg/ml
   Sample 3-10 pg/mL
   Sample 4-100 pg/ml
   Sample 5-1,000 pg/ml
   Sample 6-10,000 pg/ml
For each protein concentration tested:
   1 microlitre of magnetisable particles (Spherotech Ferromagnetic Beads 1% w/v)
   0.4 nanogram of anti-Albumin Antibody (Biotinylated “Detection” antibody from DY1455 ELISA kit).
All components mixed and sensed in a test volume of 50 microlitres.

The magnetisable particles functionalised with anti-Human Albumin antibody are added the sensing area of the microfludic chip. The samples are added to the sample port of the microfluidic chip.

The microfluidic chip is configured with a permeable plug comprising 1.5% low-melt agarose. The agarose plug is positioned in the microfluidic chip to trap 2-micrometer sized particles in an area that corresponds to the magnetic sensor. A capillary pump (passive microfluidic structure) situated downstream from the agarose pump is used to establish sufficient passive suction to draw liquid through the microfluidic chip. The agarose plug in conjunction with a 5-minute suction-induced flow downstream from the plug collects and traps the magnetisable particles into close proximity with the sensor.

Shown in Table 6 is the average sensor reading across 2,500 sample reads (for approximately 10 seconds) expressed in volts (v) for each concentration of the Human Albumin samples tested.

TABLE 6
concentration of Human Albumin vs average sensor reading

| Human Albumin protein | Sensor Value |
|---|---|
| concentration (pg/ml) | (volts - v) |
| 0 | 2.945 |
| 1 | 2.944 |
| 10 | 2.943 |
| 100 | 2.940 |
| 1,000 | 2.940 |
| 10,000 | 2.939 |

R2 value - 0.9367

The purpose of this test is to demonstrate detection of an analyte using a apparatus employing a passive system to position the particles in proximity to the sensors without the use of magnets or electromagnets.

The test described in Example 6 was varied by randomising the order in which the samples are measured to ensure readings are accurate to the sample.

The apparatus used is as described in Example 6 with the sensor data parameter summarised below.
Acquisition of sensor data:
   ^{˜}0.006 seconds per read
   1,250 reads per sample
   approximately 7 seconds total read time

The experimental protocol and microfluidic chip design is as described in Example 6.

Shown in Table 7 is the average sensor reading across 2,500 sample reads (for approximately 5 seconds) expressed in volts (v) for each concentration of the Human Albumin samples tested.

TABLE 7
concentration of Human Albumin vs average sensor reading

| Human Albumin protein | Sensor Value |
|---|---|
| concentration (pg/ml) | (volts - v) |
| 0 | 3.092 |
| 0.1 | 3.100 |
| 1 | 3.129 |
| 10 | 3.129 |
| 100 | 3.135 |

R2 value - 0.9012

The purpose of this test is to demonstrate detection of an analyte using a apparatus employing a passive system to position the particles in proximity to the sensors without the use of magnets or electromagnets.

The test described in Example 6 was varied by running the order of the samples from lowest-to-highest concentration to ensure readings are accurate to the sample. Otherwise, the apparatus and experimental protocol are as described in Example 6.

Shown in Table 8 is the average sensor reading across 2,500 sample reads (for approximately 5 seconds) expressed in volts (v) for each concentration of the Human Albumin tested.

TABLE 8
concentration of Human Albumin vs average sensor reading

| Human Albumin protein | Sensor Value |
|---|---|
| concentration (pg/ml) | (volts - v) |
| 0 | 3.072 |
| 0.1 | 3.087 |
| 1 | 3.099 |
| 10 | 3.121 |
| 100 | 3.121 |
| 1,000 | 3.120 |
| 10,000 | 3.122 |

R2 value - 0.9305

The purpose of this test is to demonstrate detection of an analyte using electrical sensing.

The electrical sensing platform is summarised below.
Copper Electrodes—0.1 mm diameter configured to a gap separation of 0.3 mm.
The Anode is connected—in series—to a 1 Ohm resistor
The entire platform is driven by a Signal Generator:
   Sine Wave Pattern-AC
   2 Volts Peak-to-Peak
   1 Megahertz Frequency
   Keithley Instruments 3390 Arbitrary Waveform Generator
Voltage Sensing was detected by an Oscilloscope:
   Agilent Technologies InfiniiVision DSO5034A
   Voltage detection of sample by probing the Cathode and Anode Copper Electrodes
   Current detection of sample by probing the Cathode and Anode of the 1 Ohm resistor
Acquisition of sensor data:
   10 microseconds per read
   1,000 reads per sample
   10 milliseconds total read time

The magnetisable particles used are Spherotech SVFM-20-5 (2.0-2.9 micrometer) Streptavidin coated ferromagnetic particles. The magnetisable particles are functionalised with biotinylated “detection” anti-Human Albumin antibody from DY1455 ELISA kit.

The experimental protocol is summarised below.
Concentrations of Human Albumin recombinant protein tested (DY1455 ELISA kit):
   Sample 1-0.1 pg/ml
   Sample 2-1 pg/mL
   Sample 3-10 pg/ml
   Sample 4-1,000 pg/ml
   Sample 5-10,000 pg/ml
For each protein concentration tested:
   1 microlitre of magnetisable particles (Spherotech Ferromagnetic Beads 1% w/v)
   0.4 nanogram of anti-Albumin Antibody (Biotinylated “Detection” antibody from DY1455 ELISA kit)
All components mixed and sensed in a test volume of 10 microlitres.

Samples were pipetted into an enclosed rectangular channel of the sample introduction device, with the Copper Electrodes stuck to the side-walls of the channel such that there is a 0.3 mm gap between the electrodes. An electromagnet was positioned directly above the channel.

After the sample is loaded into the channel of the sample introduction device, the signal generator is switched on with the setting described above. The electromagnet is switched on for 2 seconds, then switched off. The oscilloscope records with the settings described above (both voltage and current).

The sensor data is processed according to the following steps:
1. Impedance is derived by taking the voltage reading and dividing by the current reading for each time-step.
2. The change in Impedance for each time-step is derived by taking the difference between a time-step and the previous time-step.
3. The difference in impedance data is then filtered for any absolute values greater than 100 Ohms.
4. For each sample, the filtered Impedance data is then summed.

Shown in Table 9 is the sensor reading expressed as a sum of impedance (Ohms) for each concentration of the Human Albumin samples tested.

TABLE 9
Sum of Impedance (Absolute Value of
Beads Over Time 0.3mm Electrode Gap)

| Human Albumin protein | Sum of |
|---|---|
| concentration (pg/ml) | Impedance - Ohms |
| 0.1 | 35,404 |
| 1 | 90,438 |
| 10 | 323,085 |
| 1,000 | 668,479 |
| 10,000 | 913,802 |

R2 value - 0.8215

Although embodiments have been described with reference to a number of illustrative embodiments thereof, it will be understood by those skilled in the art that various changes in form and details may be made therein without departing from the spirit and scope of the invention as defined by the appended claims.

Many modifications will be apparent to those skilled in the art without departing from the scope of the present invention as herein described with reference to the accompanying drawings.

1. An apparatus for sensing of a sample comprising particles bound and unbound to an analyte, the apparatus comprising:
a sensing zone comprising at least an array of magnetic and/or electric field sensors,
a sample introduction device configured to introduce the sample to the sensing zone,
a field generator, provided the magnetisable particles do not have an aligned dipole moment, the field generator optimised for magnetic field generation if a magnetic field sensor is present and/or electrical field generator if an electric field sensor is present, the electrical field generator generating a current having a standard sine wave pattern,
provided that when a magnetic field sensor is present, the particles comprise magnetisable particles and the magnetisable particles are in a magnetised state when at the sensing zone, and
a controller connected to receive signals from the array of magnetic and/or electric field, the controller configured to determine an amount of analyte in the sample based on the signals received from the array of magnetic and/or electric field sensors,
provided that when a magnetic sensor is present the apparatus further comprises:
i) a set and reset module or capability for performing a set/reset of the magnetic sensors, or
ii) a data transmission layer, that is configured to shield the signals being transmitted from the one or more magnetic sensors, or
iii) a plurality of magnetic field transmission zones corresponding to an area below each magnetic sensor, or
iv) a printed circuit board comprising one or more vias connecting to the magnetic field sensors, or
v) any combination of two or more of (i) to (iv).

2. The apparatus of claim 1, wherein the magnetisable particles may be magnetised before binding to the analyte, or before or during introduction of the sample to the magnetic sensing zone.

3. The apparatus of claim 1, wherein the array of magnetic sensors comprises a set and reset coil/strap for performing set/reset of the magnetic sensors.

4. The apparatus of claim 1, wherein the set and reset module or capability is integrated with the magnetic sensor.

5. The apparatus of claim 1 4, wherein the magnetic sensors are set/reset between readings.

6. The apparatus of claim 1, wherein the plurality of magnetic sensors are connected in series to a calibration port such that one calibration signal is used to set/reset of the plurality of magnetic sensors.

7. The apparatus of claim 1, wherein the magnetic sensors have a sampling rate of about 0.05, 0.1, 0.5, 1, 5, 10, 15 or 20 KHz.

8. The apparatus of claim 1, wherein the magnetic sensors have a sampling rate of about 100 kHz to about 200 kHz.

9. The apparatus of claim 1, wherein at least the sensing zone is provided on an upper surface of a circuit board.

10. The apparatus of claim 9, further comprising a magnetic or electric field generator, wherein the magnetic field or electric generator is provided on a surface of the circuit board at a location corresponding to the sensing zone on the upper surface of the circuit board.

11. The apparatus of claim 9, wherein the circuit board comprises a plurality of layers.

12. The apparatus of claim 9, wherein the circuit board comprises at least one upper layer, a ground plane layer, and a lower layer and a plurality of circuit layers.

13. The apparatus of claim 9, wherein the circuit board comprises a data transmission layer, that is configured to shield the signals being transmitted from the one or more magnetic sensor from electromagnetic interference generated by the other components of the circuit board, and/or a magnetic field generator.

14. The apparatus of claim 13, wherein the data transmission layer is positioned between the upper and lower layer and upper and lower level ground planes.

15. The apparatus of claim 9, wherein the circuit board comprises a plurality of magnetic field transmission windows, each transmission window defining a portion of the circuit board that is devoid of copper layers, and transmission window corresponding to an area of the circuit board below each magnetic sensor.

16. The apparatus of claim 1, comprising a detection surface area of about 1 cm² to about 25 cm².

17. The apparatus of claim 16, wherein the detection surface comprises about 6 to about 24 magnetic sensors.

18. The apparatus of claim 1, wherein the array of magnetic sensors are closely packed.

19. The apparatus of claim 1, comprising an enclosure for housing at least one circuit board.

20. The apparatus of claim 19, wherein the enclosure comprises an integrated display configured to render a diagnostic output obtained from the circuit board.

21. The apparatus of claim 19, wherein the enclosure comprising the integrated display and at least one circuit board is configured to perform the operation of a lab-on-a-chip device.

22. The apparatus of claim 19, wherein the enclosure comprising the integrated display and a plurality of circuit boards being arranged in parallel is configured to perform the operation of a lab-on-a-bench device.

23. The apparatus of claim 19, wherein the enclosure is configured to be controlled by a user interface in the lab-on-a-chip and lab-on-a-bench device modes.

24. The apparatus of claim 1, wherein the controller is configured to controllably bias one or more of the sample introduction device, field generators, array of sensors, amplifiers and/or filters.

25. The apparatus of claim 1, wherein the controller is configured to control the bias of the sample introduction device.

26. The apparatus of claim 1, wherein the magnetisable particles have a particles size of about 1 nm to about 100 nm.

27. The apparatus of claim 1, wherein the magnetisable particles have a particles size of about 0.5 μm to 5 μm.

28. The apparatus of claim 26, wherein the controller biases the particles through the generation of an external force, the external force works to augment any inter-particle, particle-to-solvent or bonding forces.

29. The apparatus of claim 27, wherein the controller biases the particles through the generation of an external force, the external force works to fully counteract any inter-particle, particle-to-solvent or bonding forces.

30. The apparatus of claim 1, wherein the sample introduction device biases the particles relative to the sensors.

31. The apparatus of claim 9, wherein the circuit board is about 5 cm² to about 100 cm² in size.

32. The apparatus of claim 9, wherein a detection surface covers about 10% to about 50% of the circuit board surface.

33. The apparatus of claim 1, comprising a sensor for detecting an orientation of the apparatus such that the apparatus is operable in any orientation.

34. The apparatus of claim 33, wherein the sensor for detecting an orientation of the apparatus comprises one or more of a gyro-scope sensor, an inertial measurement unit, and an accelerometer.

35. The apparatus of claim 1, wherein the one or more magnetic sensors are analog sensors.

36. The apparatus of claim 1, wherein the one or more magnetic sensors comprise one or more of magneto-resistive, hall effect, and fluxgate sensors.

37. The apparatus of claim 1, comprising a signal processing module, wherein the signal processing module comprises one or more of:
an amplifier for amplifying the signal from the one or more magnetic sensors,
an analog to digital converter, and
a power supply.

38. The apparatus of claim 1, wherein when the sample introduction device is removable.

39. The apparatus of claim 1, wherein when the sample introduction device is integrated with the apparatus.

40. The apparatus of claim 1, wherein the sensing zone comprises a plurality of wells.

41. The apparatus of claim 1, as a multiplex design.

42. The apparatus of claim 41, wherein the plurality of channels are arranged in a cross-hatched configuration.

43. The apparatus of claim 1, as a parallel simplex design.

44. The apparatus of claim 41, wherein the plurality of channels are arranged in a noncross-hatched configuration.

45. The apparatus of claim 40, wherein the plurality of wells are preloaded with binding complexes.

46. The apparatus of claim 45, wherein the binding complexes are provided in a gel in the sample introduction device.

47. The apparatus of claim 45, wherein the binding complexes are provided with complementary surface chemistry to encourage complex-to-complex bonding relative to analyte load.
